(19) United States
(12) Patent Application Publication
(10) Pub. No.: US 2026/0198075 A1
(43) Pub. Date: Jul. 9, 2026

(54) SEMICONDUCTOR DEVICE

(71) Applicant: Samsung Electronics Co., Ltd., Suwon-si (KR)

(72) Inventor: Kangyoo Song, Suwon-si (KR)

(21) Appl. No.: 19/284,089

(22) Filed: Jul. 29, 2025

(30) Foreign Application Priority Data
Jan. 3, 2025 (KR) 10-2025-0001038

(51) Int. Cl. H10D 84/83; H01L 23/528; H10D 1/66; H10D 30/00; H10D 30/01; H10D 30/43; H10D 30/69; H10D 62/10; H10D 62/13; H10D 64/23; H10D 84/01

(52) U.S. Cl. CPC H10D 84/8311; H10D 30/43; H10D 30/503; H10D 30/506; H10D 62/121; H10D 62/151; H10D 64/256; H10D 84/832; H10W 20/43; H10W 20/435; H10D 1/66; H10D 30/014; H10D 30/0191; H10D 30/701; H10D 84/0128

(57) ABSTRACT

A semiconductor device includes an active pattern extending in a first direction, on a substrate, a first channel pattern and a second channel pattern provided on the active pattern and spaced apart from each other in the first direction, source/drain patterns provided at both sides of the first and second channel patterns, and gate electrodes on the first and second channel patterns. The first and second channel patterns may share one of the source/drain patterns, and a first length of the first channel pattern in the first direction may be smaller than a second length of the second channel pattern in the first direction.

### CROSS-REFERENCE TO RELATED APPLICATIONS

This U.S. non-provisional patent application claims priority under 35 U.S.C. § 119 to Korean Patent Application No. 10-2025-0001038, filed on Jan. 3, 2025, in the Korean Intellectual Property Office, the entire contents of which are hereby incorporated by reference.

### BACKGROUND

A semiconductor device includes an integrated circuit consisting of metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Thus, a variety of studies are being conducted to overcome technical limitations associated with the scale-down of the semiconductor device and to realize high performance semiconductor devices.

### SUMMARY

In general, the present disclosure is directed toward a semiconductor device having improved electrical and reliability characteristics.

According to some implementations, the present disclosure is directed to a semiconductor device that includes an active pattern extending in a first direction, on a substrate, a first channel pattern and a second channel pattern provided on the active pattern and spaced apart from each other in the first direction, source/drain patterns provided at both sides of the first and second channel patterns, and gate electrodes on the first and second channel patterns. The first and second channel patterns may share one of the source/drain patterns, and a first length of the first channel pattern in the first direction may be smaller than a second length of the second channel pattern in the first direction.

According to some implementations, the present disclosure is directed to a semiconductor device that includes an active pattern extending in a first direction, on a substrate, a channel pattern including first to third semiconductor patterns, which are spaced apart from each other on the active pattern, source/drain patterns provided at both sides of the channel pattern, inner gate electrodes between the first to third semiconductor patterns, outer gate electrodes on the third semiconductor pattern, a preliminary insulating pattern between the outer gate electrodes, and a gate spacer between the outer gate electrodes and the preliminary insulating pattern. The preliminary insulating pattern may be vertically overlapped with the first to third semiconductor patterns.

According to some implementations, the present disclosure is directed to a semiconductor device that includes a first active pattern and a second active pattern, which are provided on a substrate and are spaced apart from each other, a first channel pattern and a second channel pattern on the first active pattern, a third channel pattern and a fourth channel pattern on the second active pattern, first source/drain patterns provided at both sides of the first and second channel patterns, second source/drain patterns provided at both sides of the third and fourth channel patterns, gate electrodes on the first to fourth channel patterns, a gate insulating layer between the first to fourth channel patterns and the gate electrodes, and a preliminary insulating pattern on the second channel pattern and the fourth channel pattern. The first source/drain patterns may be spaced apart from each other by at least two different distances, and the second source/drain patterns may be spaced apart from each other by at least two different distances.

### BRIEF DESCRIPTION OF THE DRAWINGS

Example implementations will be more clearly understood from the following detailed explanations, taken in conjunction with the accompanying drawings.

FIG. 1 is a plan view illustrating an example arrangement of logic cells according to some implementations.

FIG. 2 is an enlarged plan view illustrating an example of a portion (e.g., X of FIG. 1) of a semiconductor device according to some implementations.

FIGS. 3A to 3E are sectional views taken along lines A-A′, B-B′, C-C′, D-D′, and E-E′ of FIG. 2 illustrating an example of a semiconductor device according to some implementations.

FIG. 4A is an enlarged sectional view illustrating an example of a portion ‘P1’ of FIG. 3A according to some implementations.

FIG. 4B is an enlarged sectional view illustrating an example of a portion ‘P2’ of FIG. 3B according to some implementations.

FIG. 5 is an enlarged plan view illustrating an example of a portion (e.g., Y of FIG. 1) of semiconductor device according to some implementations.

FIGS. 6A and 6B are sectional views taken along lines A-A′ and B-B′ of FIG. 5 illustrating an example of a semiconductor device according to some implementations.

FIGS. 7A, 7B, 8A-8C, 9A-9C, 10A-10E, 11A-11E, and 12A-12E are sectional views illustrating an example of a method of fabricating a semiconductor device according to some implementations.

### DETAILED DESCRIPTION

Hereinafter, example implementations will be explained in detail with reference to the accompanying drawings. Like reference numerals in the drawings denote like elements, and thus their description will be omitted.

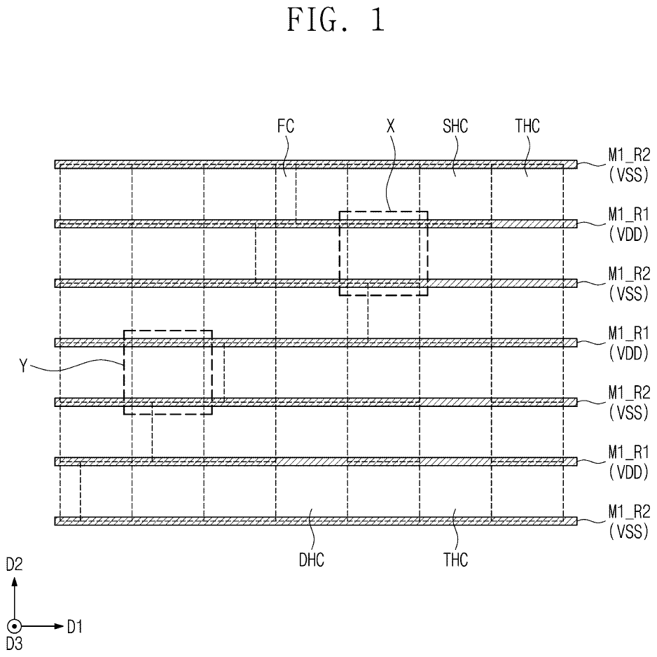

FIG. 1 is a plan view illustrating an example arrangement of logic cells according to some implementations. In FIG. 1, a semiconductor device may include a plurality of logic cells. The semiconductor device may be fabricated based on a designed layout. The layout of the semiconductor device may be generated using, for example, a layout design tool.

First and second power interconnection lines M1_R1 and M1_R2 may be placed on the layout. For example, the first power interconnection lines M1_R1 may be defined as a conduction path of a drain voltage VDD, and the second power interconnection lines M1_R2 may be defined as a conduction path of a source voltage VSS. Each of the first and second power interconnection lines M1_R1 and M1_R2 may be extended in a first direction D1. The first and second power interconnection lines M1_R1 and M1_R2 may be alternately placed at a constant pitch in a second direction D2.

In the present disclosure, the first and second directions D1 and D2 may not be parallel to each other. A third direction D3 may not be parallel to the first and second directions D1 and D2. For example, the first direction D1, the second direction D2, and the third direction D3 may be orthogonal to each other. Each of the first and second directions D1 and D2 may be referred to as a horizontal direction, and the third direction D3 may be referred to as a vertical direction.

A plurality of logic cells and a plurality of filler cells FC may be provided between the first and second power interconnection lines M1_R1 and M1_R2. The logic cells may include a single height cell SHC, a double height cell DHC, and a triple height cell THC. For example, the single height cell SHC may be composed of a single logic cell. The double height cell DHC may be composed of two logic cells, which are adjacent to each other. The triple height cell THC may be composed of three logic cells, which are adjacent to each other. In some implementations, a plurality of single height cells SHC, a plurality of double height cells DHC, and a plurality of triple height cells THC may be provided.

Each of the filler cells FC may be located between the logic cells, which are adjacent to each other. The filler cells FC may fill an empty space between the logic cells. For example, each of the filler cells FC may be a dummy cell.

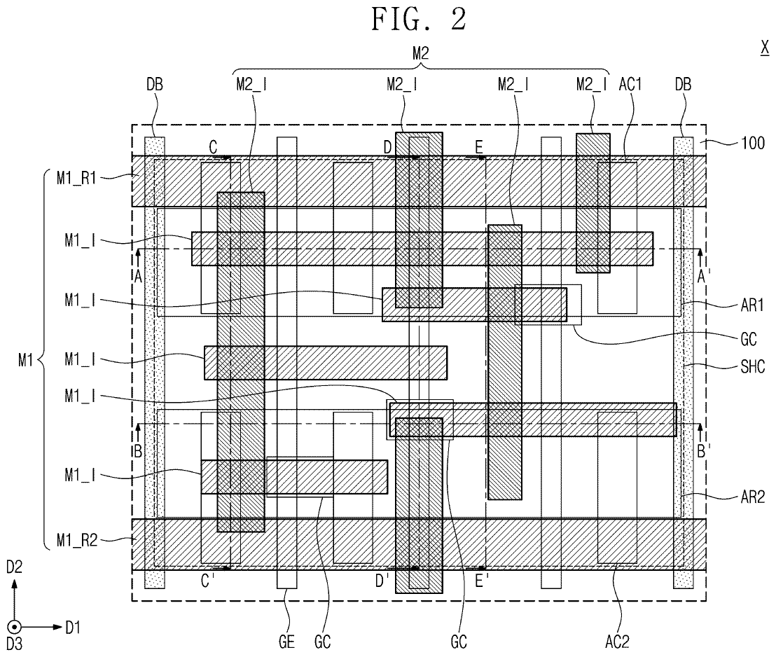

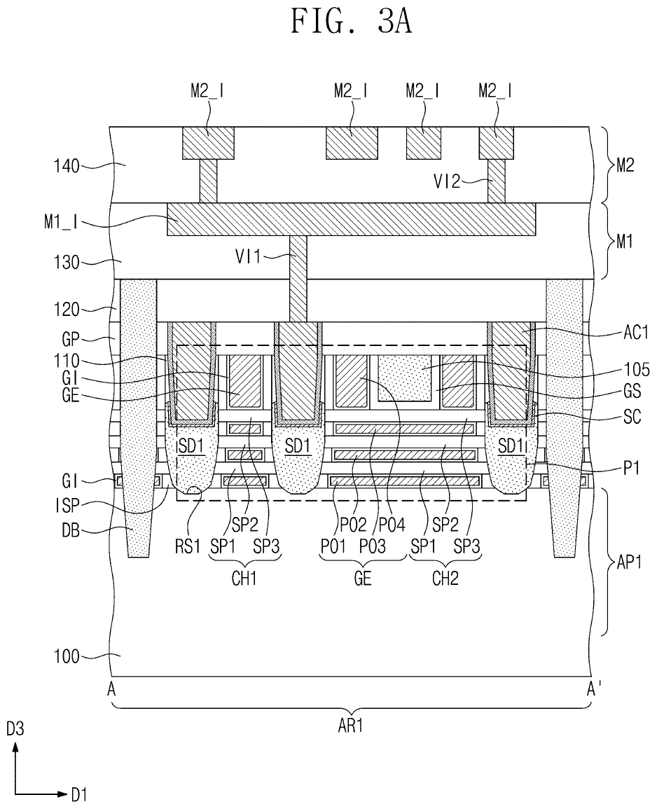

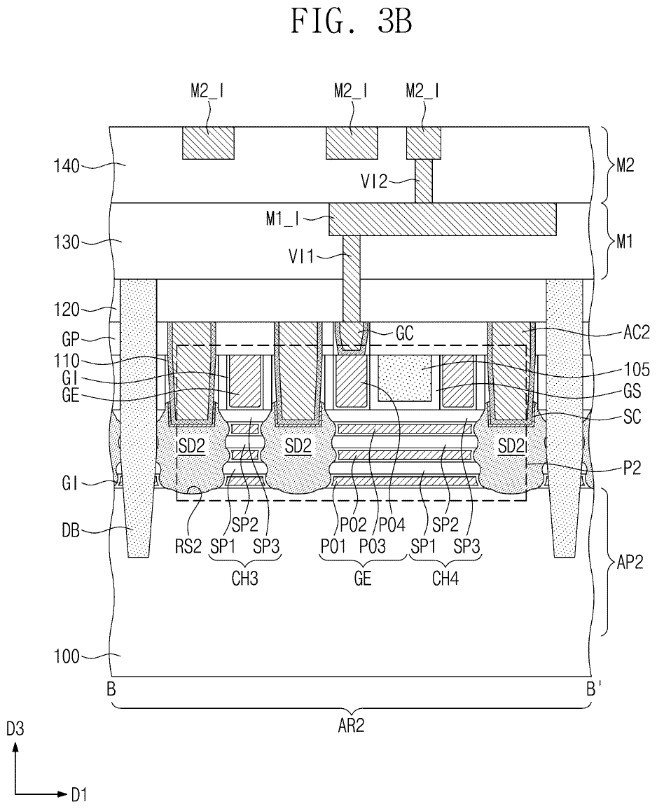

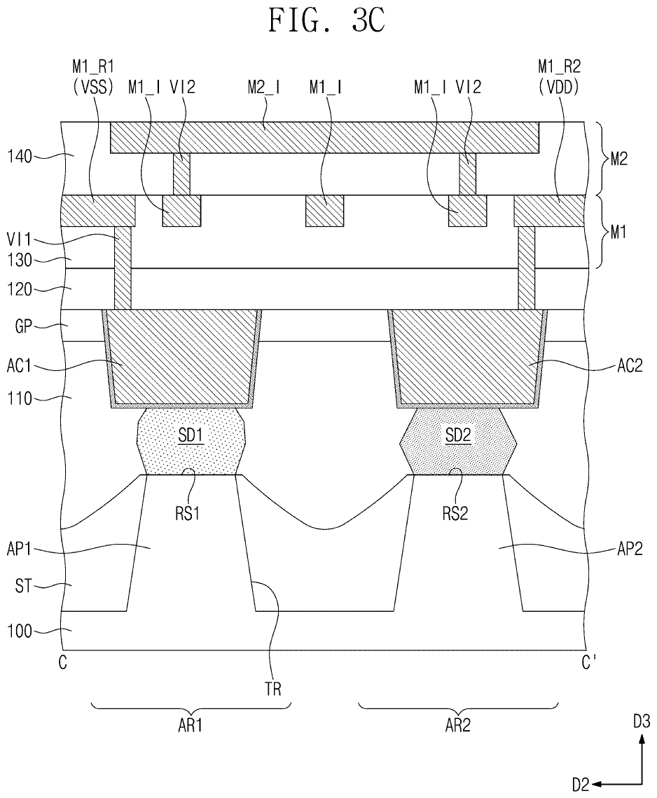

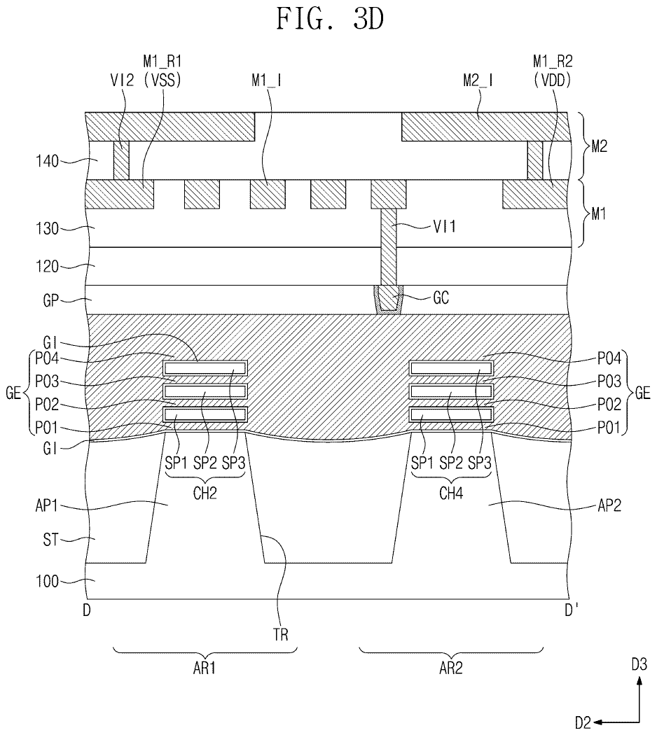

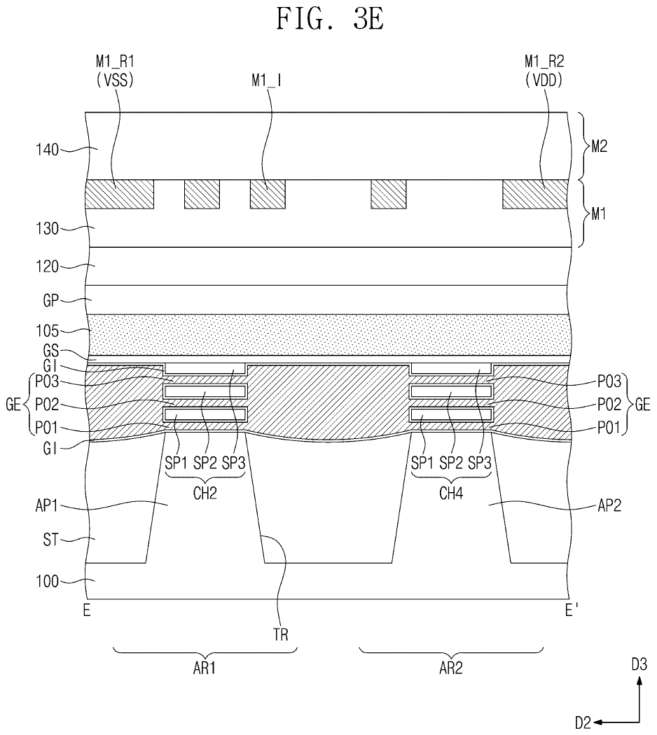

FIG. 2 is an enlarged plan view illustrating an example of a portion (e.g., X of FIG. 1) of a semiconductor device according to some implementations. FIGS. 3A to 3E are sectional views taken along lines A-A′, B-B′, C-C′, D-D′, and E-E′ of FIG. 2 illustrating an example of a semiconductor device according to some implementations.

In FIGS. 2 and 3A to 3E, the single height cell SHC may be provided on a substrate 100. Logic transistors constituting a logic circuit may be disposed on the single height cell SHC. The substrate 100 may be a semiconductor substrate that is formed of or includes silicon, germanium, silicon germanium, a compound semiconductor material, or the like. For example, the substrate 100 may be a silicon substrate.

The substrate 100 may include a first active region AR1 and a second active region AR2. Each of the first and second active regions AR1 and AR2 may be extended in the first direction D1. For example, the first active region AR1 may be an NMOSFET region, and the second active region AR2 may be a PMOSFET region.

A first active pattern AP1 and a second active pattern AP2 may be provided on the substrate 100. The first and second active patterns AP1 and AP2 may be defined by a trench TR, which is formed in an upper portion of the substrate 100. The first active pattern AP1 may be provided on the first active region AR1, and the second active pattern AP2 may be provided on the second active region AR2. The first and second active patterns AP1 and AP2 may be extended in the first direction D1. Each of the first and second active patterns AP1 and AP2 may be a vertically-protruding portion of the substrate 100.

A device isolation layer ST may be provided on the substrate 100. The device isolation layer ST may be provided to fill the trench TR and to cover side surfaces of the first and second active patterns AP1 and AP2. The device isolation layer ST may include a silicon oxide layer. The device isolation layer ST may not cover first to fourth channel patterns CH1, CH2, CH3, and CH4, which will be described below.

A first channel pattern CH1 and a second channel pattern CH2 may be provided on the first active pattern AP1. A third channel pattern CH3 and a fourth channel pattern CH4 may be provided on the second active pattern AP2. Each of the first to fourth channel patterns CH1, CH2, CH3, and CH4 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in the third direction D3.

Each of the first to third semiconductor patterns SP1, SP2, and SP3 may include silicon, germanium, or silicon-germanium. For example, each of the first to third semiconductor patterns SP1, SP2, and SP3 may be formed of or include crystalline silicon (e.g., single-crystalline silicon). In some implementations, the first to third semiconductor patterns SP1, SP2, and SP3 may be nanosheets that are stacked.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The distances between the first source/drain patterns SD1 may be different in the first direction D1. The first and second channel patterns CH1 and CH2 may be placed between the first source/drain patterns SD1, which are adjacent to each other in the first direction D1. For example, the first and second channel patterns CH1 and CH2 may share a single first source/drain pattern SD1 therebetween. In addition, the first to third semiconductor patterns SP1, SP2, and SP3 of the first and second channel patterns CH1 and CH2 may connect the first source/drain patterns SD1, which are adjacent to each other in the first direction D1, to each other.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2l, respectively. The second source/drain patterns SD2 may be impurity regions of a second conductivity type (e.g., p-type). The distances between the second source/drain patterns SD2 may be different in the first direction D1. The third and fourth channel patterns CH3 and CH4 may be placed between the second source/drain patterns SD2, which are adjacent to each other in the first direction D1. For example, the third and fourth channel patterns CH3 and CH4 may share a single second source/drain pattern SD2 therebetween. In addition, the first to third semiconductor patterns SP1, SP2, and SP3 of the third and fourth channel patterns CH3 and CH4 may connect the second source/drain patterns SD2, which are adjacent to each other in the first direction D1, to each other.

The first and second source/drain patterns SD1 and SD2 may be epitaxial patterns, which are formed by a selective epitaxial growth (SEG) process. For example, a top surface of each of the first and second source/drain patterns SD1 and SD2 may be higher than a top surface of the third semiconductor pattern SP3. In some implementations, at least one of the top surfaces of the first and second source/drain patterns SD1 and SD2 may be located at substantially the same level as the top surface of the third semiconductor pattern SP3.

In some implementations, the first source/drain patterns SD1 may be formed of or include the same semiconductor material (e.g., Si) as the substrate 100. The second source/drain patterns SD2 may include a semiconductor material (e.g., SiGe) having a larger lattice constant than the substrate 100. Accordingly, the second source/drain patterns SD2, which are adjacent to each other in the first direction D1, may exert a compressive stress on the third and fourth channel patterns CH3 and CH4 therebetween.

In some implementations, the second source/drain pattern SD2 may have an uneven or embossing side surface. For example, the side surfaces of the second source/drain patterns SD2 may have a wave-shaped profile. The side surfaces of the second source/drain patterns SD2 may protrude toward first to third inner gate electrodes PO1, PO2, and PO3 of a gate electrodes GE, which will be described below.

The gate electrodes GE may be provided on the first to fourth channel patterns CH1, CH2, CH3, and CH4. Each of the gate electrodes GE may be extended in the second direction D2 to cross the first to fourth channel patterns CH1, CH2, CH3, and CH4. Each of the gate electrodes GE may be vertically overlapped with the first to fourth channel patterns CH1, CH2, CH3, and CH4. The gate electrodes GE may be spaced apart from each other in the first direction D1.

Each of the gate electrodes GE may include first to third inner gate electrodes PO1, PO2, and PO3 and an outer gate electrode PO4. The first inner gate electrode PO1 may be placed between the first or second active pattern AP1 or AP2 and the first semiconductor pattern SP1. The second inner gate electrode PO2 may be placed between the first semiconductor pattern SP1 and the second semiconductor pattern SP2. The third inner gate electrode PO3 may be placed between the second semiconductor pattern SP2 and the third semiconductor pattern SP3. The outer gate electrode PO4 may be placed on the third semiconductor pattern SP3. In some implementations, some of the gate electrodes GE may include a plurality of outer gate electrodes PO4.

Each of the gate electrodes GE may be provided on a top surface, a bottom surface, and opposite side surfaces of each of the first to third semiconductor patterns SP1, SP2, and SP3. That is, the transistor may be a three-dimensional field effect transistor (e.g., MBCFET or GAAFET) in which the gate electrode GE is provided to three-dimensionally surround the channel pattern.

Inner spacers ISP may be provided on the first active region AR1 and may be respectively interposed between the first to third inner gate electrodes PO1, PO2, and PO3 of the gate electrodes GE and the first source/drain patterns SD1. The first to third inner gate electrodes PO1, PO2, and PO3 of the gate electrodes GE may be spaced apart from the first source/drain patterns SD1 with the inner spacers ISP interposed therebetween. The inner spacers ISP may include an insulating material and may prevent a leakage current from the gate electrodes GE.

A pair of gate spacers GS may be respectively disposed on opposite side surfaces of the outer gate electrode PO4 of each of the gate electrodes GE. The gate spacers GS may be extended in the second direction D2 or along the gate electrodes GE. For example, the gate spacers GS may include at least one of SiCN, SiCON, or SiN. In some implementations, the gate spacers GS may have a multi-layered structure including at least two of SiCN, SiCON, or SiN.

A preliminary insulating pattern 105 extending in the second direction D2 may be provided on the second and fourth channel patterns CH2 and CH4. More specifically, the preliminary insulating pattern 105 may be placed on the third semiconductor pattern SP3 of each of the second and fourth channel patterns CH2 and CH4. That is, the preliminary insulating pattern 105 may be vertically overlapped with the second and fourth channel patterns CH2 and CH4. In addition, the preliminary insulating pattern 105 may be placed between the outer gate electrodes PO4 of some of the gate electrodes GE. For example, the preliminary insulating pattern 105 may be placed between two outer gate electrodes PO4. A top surface of the preliminary insulating pattern 105 may be placed on the same plane as top surfaces of the outer gate electrodes PO4. The preliminary insulating pattern 105 may be formed of or include at least one of silicon oxide, silicon nitride, and/or silicon oxynitride.

In some implementations, one of the gate spacers GS adjacent to the preliminary insulating pattern 105 may be extended to a region between the preliminary insulating pattern 105 and the third semiconductor pattern SP3 of each of the second and fourth channel patterns CH2 and CH4. Accordingly, the gate spacers GS adjacent to the preliminary insulating pattern 105 may be connected to each other to form a single gate spacer GS. For example, the gate spacer GS adjacent to the preliminary insulating pattern 105 may have a U-shaped section. The gate spacer GS adjacent to the preliminary insulating pattern 105 may be in contact with a bottom surface of the preliminary insulating pattern 105. In addition, the gate spacer GS adjacent to the preliminary insulating pattern 105 may be in contact with a top surface of the third semiconductor pattern SP3 of each of the second and fourth channel patterns CH2 and CH4. That is, the gate spacer GS adjacent to the preliminary insulating pattern 105 may be in contact with a portion of the second and fourth channel patterns CH2 and CH4.

A gate insulating layer GI may be provided between the gate electrodes GE and the first to fourth channel patterns CH1, CH2, CH3, and CH4. For example, the gate insulating layer GI may be placed between the first to third semiconductor patterns SP1, SP2, and SP3 and the first to third inner gate electrodes PO1, PO2, and PO3 and between the third semiconductor pattern SP3 and the outer gate electrode PO4. The gate insulating layer GI may cover a top surface, a bottom surface, and opposite side surfaces of each of the first to third semiconductor patterns SP1, SP2, and SP3 of the first and third channel patterns CH1 and CH3. The gate insulating layer GI may partially cover a top surface, a bottom surface, and opposite side surfaces of each of the first to third semiconductor patterns SP1, SP2, and SP3 of the second and fourth channel patterns CH2 and CH4. For example, the gate insulating layer GI may not cover a portion of a top surface of the third semiconductor pattern SP3 of each of the second and fourth channel patterns CH2 and CH4. The gate insulating layer GI may be extended to a region below a bottom surface of the gate spacer GS adjacent to the preliminary insulating pattern 105. The gate insulating layer GI may be in contact with a portion of the bottom surface of the gate spacer GS, which is adjacent to the preliminary insulating pattern 105 and is not in contact with the third semiconductor pattern SP3 of each of the second and fourth channel patterns CH2 and CH4. In addition, the gate insulating layer GI may cover a top surface of the device isolation layer ST below the gate electrodes GE.

The gate insulating layer GI may include a silicon oxide layer, a silicon oxynitride layer, and/or a high-k dielectric layer. In some implementations, the gate insulating layer GI may have a structure, in which a silicon oxide layer and a high-k dielectric layer are stacked. In the present disclosure, the high-k dielectric layer may be formed of or include a high-k dielectric material having a higher dielectric constant than the silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some implementations, the semiconductor device may include a negative capacitance (NC) FET using a negative capacitor. In this case, the gate insulating layer GI may include a ferroelectric layer having a ferroelectric property and a paraelectric layer having a paraelectric property. For example, the gate insulating layer GI may include a single ferroelectric layer. In some implementations, the gate insulating layer GI may include a plurality of ferroelectric layers, which are spaced apart from each other. In some implementations, the gate insulating layer GI may have a stacking structure, in which a plurality of ferroelectric layers and a plurality of paraelectric layers are alternately stacked.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected capacitors has a negative capacitance, a total capacitance of the serially-connected capacitors may have a positive value and may be greater than an absolute value of each capacitance. In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than about 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. The hafnium zirconium oxide may be, for example, hafnium oxide with doped with zirconium. In some implementations, the hafnium zirconium oxide may be a compound of hafnium, zirconium, and oxygen.

The ferroelectric layer may further include dopants. For example, the dopants may include at least one of aluminum, titanium, niobium, lanthanum, yttrium, magnesium, silicon, calcium, cerium, dysprosium, erbium, gadolinium, germanium, scandium, strontium, or tin. The kind of the dopants in the ferroelectric layer may vary depending on a ferroelectric material included in the ferroelectric layer.

The paraelectric layer may have the paraelectric property. For example, the paraelectric layer may include at least one of silicon oxide or metal oxide materials having high-k dielectric constants. The metal oxides, which can be used as the paraelectric layer, may include at least one of, for example, hafnium oxide, zirconium oxide, and/or aluminum oxide, but the inventive concept is not limited to these examples.

A first interlayer insulating layer 110 may be provided on the substrate 100. The first interlayer insulating layer 110 may cover the gate spacers GS, the first and second source/drain patterns SD1 and SD2, and the device isolation layer ST. A top surface of the first interlayer insulating layer 110 may be substantially coplanar with top surfaces of the gate spacers GS.

A gate capping layer GP may be provided on the gate electrodes GE, the preliminary insulating pattern 105, and the first interlayer insulating layer 110. The gate capping layer GP may be extended in the first and second directions D1 and D2 and may cover the gate electrodes GE and the preliminary insulating pattern 105. The gate capping layer GP may be formed of or include at least one of, for example, SiON, SiCN, SiCON, or SiN.

First and second active contacts AC1 and AC2 may be provided to penetrate the first interlayer insulating layer 110 and the gate capping layer GP and may be electrically connected to the first and second source/drain patterns SD1 and SD2, respectively. The gate electrodes GE may be placed between the first active contacts AC1, which are adjacent to each other in the first direction D1 and between the second active contacts AC2, which are adjacent to each other in the first direction D1. When viewed in a plan view, each of the first and second active contacts AC1 and AC2 may have a bar-shaped structure extending in the second direction D2.

In some implementations, each of the first and second active contacts AC1 and AC2 may include a conductive pattern and a barrier pattern enclosing the conductive pattern. The barrier pattern may cover side and bottom surfaces of the conductive pattern. The conductive pattern may be formed of or include at least one of metallic materials (e.g., aluminum, copper, tungsten, molybdenum, and cobalt). The barrier pattern may be a metal layer, which is formed of or includes at least one of titanium, tantalum, tungsten, nickel, cobalt, or platinum, or a metal nitride layer, which is formed of or includes at least one of titanium nitride, tantalum nitride, tungsten nitride, nickel nitride, cobalt nitride, or platinum nitride.

A metal-semiconductor compound layer SC may be provided between the first active contacts AC1 and the first source/drain patterns SD1 and between the second active contacts AC2 and the second source/drain patterns SD2. The first and second active contacts AC1 and AC2 may be electrically connected to the first and second source/drain patterns SD1 and SD2, respectively, through the metal-semiconductor compound layer SC. For example, the metal-semiconductor compound layer SC may be formed of or include at least one of titanium silicide, tantalum silicide, tungsten silicide, nickel silicide, or cobalt silicide. Accordingly, it may be possible to improve the contact resistance characteristics between the first active contacts AC1 and the first source/drain patterns SD1 and between the second active contacts AC2 and the second source/drain patterns SD2.

Gate contacts GC may be provided to penetrate the gate capping layer GP and may be electrically connected to the gate electrodes GE. Similar to the first and second active contacts AC1 and AC2, each of the gate contacts GC may include a conductive pattern and a barrier pattern enclosing the conductive pattern. When viewed in a plan view, the gate contacts GC may be overlapped with the first or second active region AR1 or AR2.

A second interlayer insulating layer 120 may be disposed on the gate capping layer GP. A third interlayer insulating layer 130 may be provided on the second interlayer insulating layer 120. A fourth interlayer insulating layer 140 may be provided on the third interlayer insulating layer 130. In some implementations, each of the first to fourth interlayer insulating layers 110, 120, 130, and 140 may include a silicon oxide layer.

A pair of division structures DB, which are opposite to each other in the first direction D1, may be provided at both sides of the single height cell SHC. For example, the pair of division structures DB may be placed on a border defining the single height cell SHC. Each of the division structures DB may be extended in the second direction D2.

The division structures DB may be provided to penetrate the gate capping layer GP and the second interlayer insulating layer 120 and may be extended into the first and second active patterns AP1 and AP2. The division structures DB may be provided to penetrate an upper portion of each of the first and second active patterns AP1 and AP2. The division structures DB may electrically separate the active region of the single height cell SHC from the active regions of other logic cells adjacent thereto.

A first metal layer M1 may be provided in the third interlayer insulating layer 130. For example, the first metal layer M1 may include a first power line M1_R1, a second power line M1_R2, and first interconnection lines M1_I. The interconnection lines M1_R1, M1_R2, and M1_I of the first metal layer M1 may be extended in the first direction D1 and parallel to each other. For example, each of the first and second power interconnection lines M1_R1 and M1_R2 may be placed on a border of the single height cell SHC. The first interconnection lines M1_I may be placed between the first and second power interconnection lines M1_R1 and M1_R2. The first interconnection lines M1_I may be spaced apart from each other in the second direction D2.

The first metal layer M1 may further include first vias VI1. The first vias VI1 may be provided below the interconnection lines M1_R1, M1_R2, and M1_I of the first metal layer M1. The first active contacts AC1, the second active contacts AC2 and the gate contacts GC and the interconnection lines M1_R1, M1_R2, and M1_I of the first metal layer M1 may be electrically connected to each other through the first vias VI1. For this, the first vias VI1 may be extended into the second interlayer insulating layer 120.

A second metal layer M2 may be provided in the fourth interlayer insulating layer 140. The second metal layer M2 may include a plurality of second interconnection lines M2_I. Each of the second interconnection lines M2_I of the second metal layer M2 may be extended in the second direction D2. The second interconnection lines M2_I may be spaced apart from each other in the first direction D1.

The second metal layer M2 may further include second vias VI2, which are provided below the second interconnection lines M2_I, respectively. The interconnection lines M1_R1, M1_R2, and M1_I of the first metal layer M1 and the second interconnection lines M2_I of the second metal layer M2 may be electrically connected to each other through the second vias VI2.

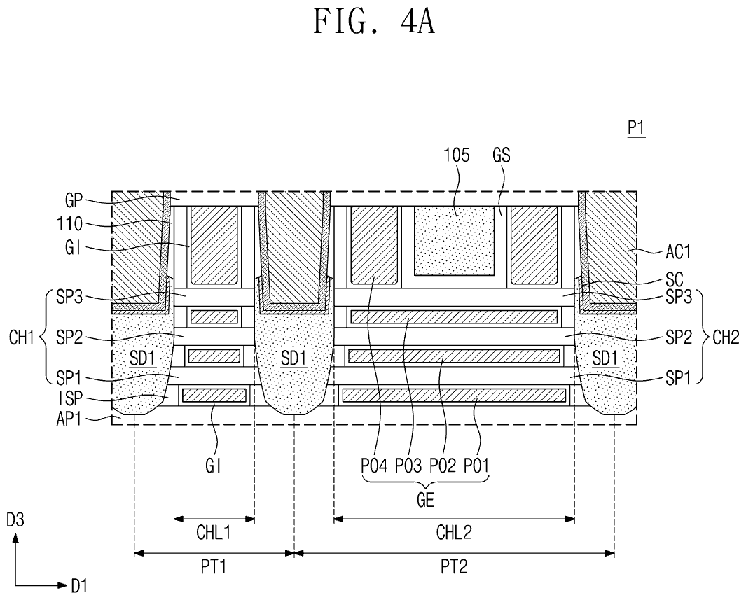

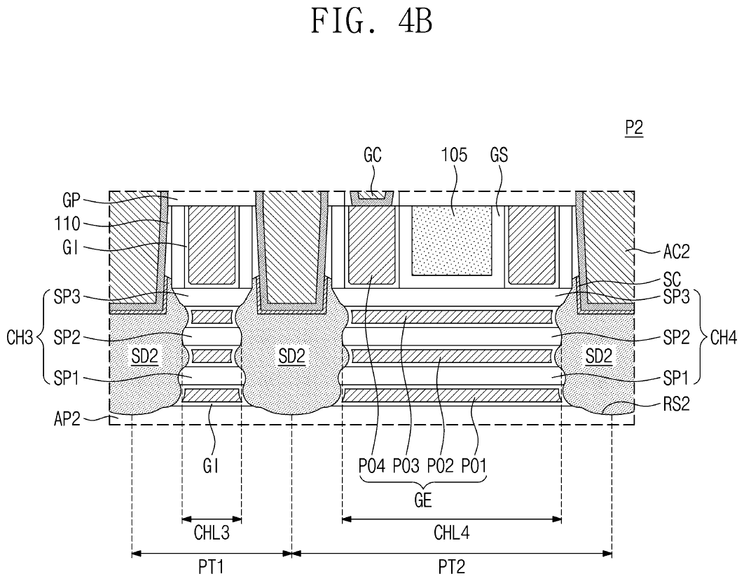

FIG. 4A is an enlarged sectional view illustrating an example of a portion ‘P1’ of FIG. 3A according to some implementations. FIG. 4B is an enlarged sectional view illustrating an example of a portion ‘P2’ of FIG. 3B according to some implementations.

In FIGS. 4A and 4B, the distances between the first source/drain patterns SD1 may be different. For example, a distance, in the first direction D1, between the first source/drain patterns SD1 at opposite sides of the first channel pattern CH1 may be a first pitch PT1. A distance, in the first direction D1, between the first source/drain patterns SD1 at opposite sides of the second channel pattern CH2 may be a second pitch PT2. The first and second pitches PT1 and PT2 may be different from each other. That is, the first source/drain pattern SD1, which is shared by the first and second channel patterns CH1 and CH2, may be spaced at different distances from other first source/drain patterns SD1.

The second source/drain patterns SD2 may be disposed in substantially the same manner as the first source/drain patterns SD1. For example, a distance, in the first direction D1, between the second source/drain patterns SD2 at opposite sides of the third channel pattern CH3 may be the first pitch PT1. A distance, in the first direction D1, between the second source/drain patterns SD2 at opposite sides of the fourth channel pattern CH4 may be the second pitch PT2 different from the first pitch PT1. That is, the second source/drain pattern SD2, which is shared by the third and fourth channel patterns CH3 and CH4, may be spaced at different distances from other second source/drain patterns SD2.

The first pitch PT1 between the first source/drain patterns SD1 may be substantially equal to the first pitch PT1 between the second source/drain patterns SD2. The second pitch PT2 between the first source/drain patterns SD1 may be substantially equal to the second pitch PT2 between the second source/drain patterns SD2. In addition, the first pitch PT1 may be smaller than the second pitch PT2. For example, the second pitch PT2 may be about two times the first pitch PT1. Accordingly, the length of each of the first to fourth channel patterns CH1, CH2, CH3, and CH4 in the first direction D1 may be different from the length of each of the first to third inner gate electrodes PO1, PO2, and PO3 of the gate electrodes GE.

Each of the first and second channel patterns CH1 and CH2 on the first active pattern AP1 may have a horizontal length in the first direction D1. For example, the first channel pattern CH1 may have a first length CHL1 in the first direction D1, and the second channel pattern CH2 may have a second length CHL2 in the first direction D1. The first length CHL1 of the first channel pattern CH1 may be smaller than the second length CHL2 of the second channel pattern CH2. More specifically, the second length CHL2 of the second channel pattern CH2 may be larger than two times the first length CHL1 of the first channel pattern CH1.

Each of the third and fourth channel patterns CH3 and CH4 on the second active pattern AP2 may have a horizontal length in the first direction D1. For example, the third channel pattern CH3 may have a third length CHL3 in the first direction D1, and the fourth channel pattern CH4 may have a fourth length CHL4 in the first direction D1. For example, the third length CHL3 of the third channel pattern CH3 may be substantially equal to the first length CHL1 of the first channel pattern CH1. The fourth length CHL4 of the fourth channel pattern CH4 may be substantially equal to the second length CHL2 of the second channel pattern CH2. Accordingly, the fourth length CHL4 of the fourth channel pattern CH4 may be larger than two times the third length CHL3 of the third channel pattern CH3.

In the present disclosure, the horizontal length of each of the first to fourth channel patterns CH1, CH2, CH3, and CH4 may refer to the average value of lengths, in the first direction D1, of the first to third semiconductor patterns SP1, SP2, and SP3 that are included in each of the first to fourth channel patterns CH1, CH2, CH3, and CH4.

Since the first and second channel patterns CH1 and CH2 have different lengths from each other in the first direction D1, the gate electrodes GE on the first and second channel patterns CH1 and CH2 may have different lengths from each other in the first direction D1. More specifically, the length of each of the first to third inner gate electrodes PO1, PO2, and PO3 between the first to third semiconductor patterns SP1, SP2, and SP3 of the first channel pattern CH1 may be substantially equal to or smaller than the first length CHL1 of the first channel pattern CH1. The length of each of the first to third inner gate electrodes PO1, PO2, and PO3 between the first to third semiconductor patterns SP1, SP2, and SP3 of the second channel pattern CH2 may be substantially equal to or smaller than the second length CHL2 of the second channel pattern CH2. For example, the length of each of the first to third inner gate electrodes PO1, PO2, and PO3 in the first channel pattern CH1 may be smaller than the length of each of the first to third inner gate electrodes PO1, PO2, and PO3 in the second channel pattern CH2. More specifically, the length of each of the first to third inner gate electrodes PO1, PO2, and PO3 in the second channel pattern CH2 may be larger than two times the length of each of the first to third inner gate electrodes PO1, PO2, and PO3 in the first channel pattern CH1.

Similar to the gate electrodes GE on the first and second channel patterns CH1 and CH2, the gate electrodes GE on the third and fourth channel patterns CH3 and CH4 may have different lengths from each other in the first direction D1. For example, the length of each of the first to third inner gate electrodes PO1, PO2, and PO3 in the fourth channel pattern CH4 may be larger than two times the length of each of the first to third inner gate electrodes PO1, PO2, and PO3 in the third channel pattern CH3.

That is, the first to third inner gate electrodes PO1, PO2, and PO3 may have different lengths from each other in the first direction D1, in the first and second channel patterns CH1 and CH2 or in the third and fourth channel patterns CH3 and CH4.

Each of the gate electrodes GE on the second and fourth channel patterns CH2 and CH4 may include two outer gate electrodes PO4. The length of each of the outer gate electrodes PO4 on the second and fourth channel patterns CH2 and CH4 may be substantially equal to the length of the outer gate electrode PO4 on the first and third channel patterns CH1 and CH3. That is, the outer gate electrodes PO4 on the first to fourth channel patterns CH1, CH2, CH3, and CH4 may have substantially the same length in the first direction D1.

Accordingly, a length of each of the first to third inner gate electrodes PO1, PO2, and PO3 in the first and third channel patterns CH1 and CH3 in the first direction D1 may be substantially equal to a length of the outer gate electrode PO4 on the first and third channel patterns CH1 and CH3 in the first direction D1. The length of each of the first to third inner gate electrodes PO1, PO2, and PO3 in the second and fourth channel patterns CH2 and CH4 in the first direction D1 may be larger than the length of each of the outer gate electrodes PO4 on the second and fourth channel patterns CH2 and CH4 in the first direction D1. For example, the length of each of the first to third inner gate electrodes PO1, PO2, and PO3 in the second and fourth channel patterns CH2 and CH4 in the first direction D1 may be larger than two times the length of each of the outer gate electrodes PO4 on the second and fourth channel patterns CH2 and CH4 in the first direction D1.

In the semiconductor device, transistors with different channel lengths may be provided i a single logic cell. For example, a channel length of the transistors, which are composed of the first and third channel patterns CH1 and CH3, may be smaller than a channel length of the transistors, which are composed of the second and fourth channel patterns CH2 and CH4. Accordingly, the transistors with various channel lengths may form a single logic cell.

In addition, the transistors, which are composed of the second and fourth channel patterns CH2 and CH4 with a relatively long channel length, may be used as MOS capacitors. In this case, the logic cell may serve as a passive device.

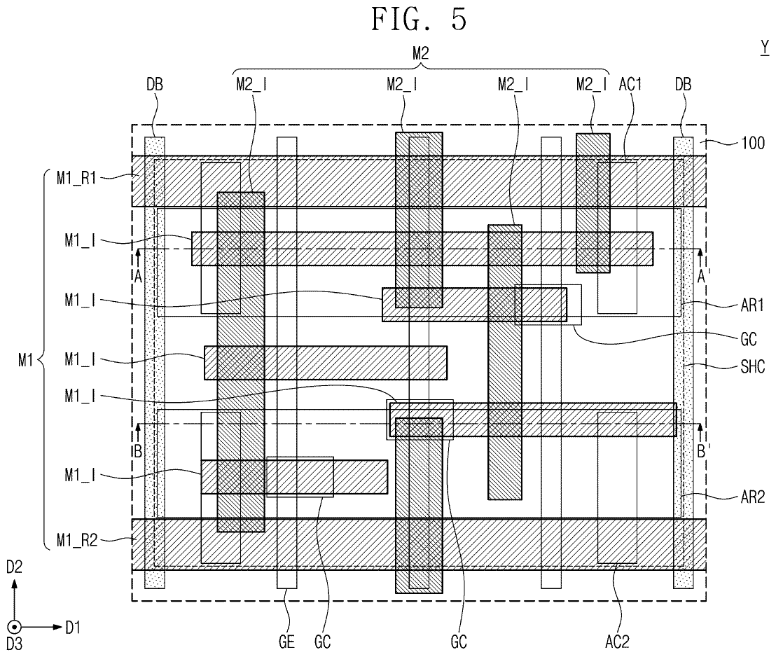

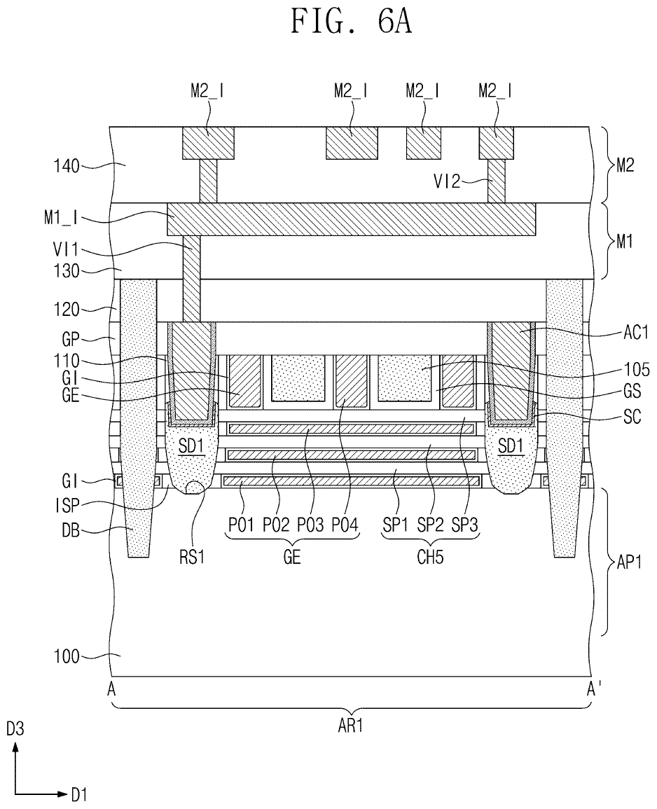

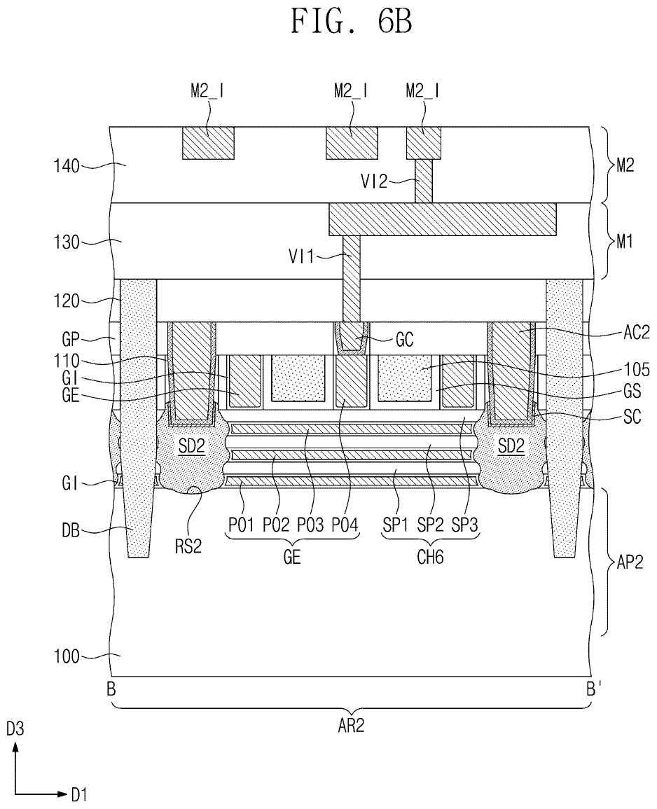

FIG. 5 is an enlarged plan view illustrating an example of a portion (e.g., Y of FIG. 1) of a semiconductor device according to some implementations. FIGS. 6A and 6B are sectional views taken along lines A-A′ and B-B′ of FIG. 5 illustrating an example of a semiconductor device according to some implementations.

In the following description, an element previously described with reference to FIGS. 2 and 3A to 3E may be identified by the same reference number without repeating an overlapping description thereof, for concise description.

In FIGS. 5, 6A, and 6B, the substrate 100 may include the first active region AR1 and the second active region AR2, the first active pattern AP1 may be provided on the first active region AR1 of the substrate 100, and the second active pattern AP2 may be provided on the second active region AR2 of the substrate 100. The first active pattern AP1, the second active pattern AP2, and the device isolation layer ST defining the first and second active patterns AP1 and AP2 may be provided to have substantially the same features as those in the implementations of FIGS. 2 and 3A to 3E.

The first source/drain patterns SD1 and a fifth channel pattern CH5, which is provided between the first source/drain patterns SD1, may be provided on the first active pattern AP1. The second source/drain patterns SD2 and a sixth channel pattern CH6, which is provided between the second source/drain patterns SD2, may be provided on the second active pattern AP2. Each of the fifth and sixth channel patterns CH5 and CH6 may include the first to third semiconductor patterns SP1, SP2, and SP3, which are sequentially stacked.

A distance between the first source/drain patterns SD1 in the first direction D1 and a distance between the second source/drain patterns SD2 in the first direction D1 may be larger than the first and second pitches PT1 and PT2 described with reference to FIGS. 4A and 4B. For example, the distance between the first source/drain patterns SD1 and the distance between the second source/drain patterns SD2 may be substantially equal to a sum of the first and second pitches PT1 and PT2 of FIGS. 4A and 4B.

Each of the fifth and sixth channel patterns CH5 and CH6 may have a horizontal length in the first direction D1. The length of the fifth channel pattern CH5 in the first direction D1 may be substantially equal to the length of the sixth channel pattern CH6 in the first direction D1. For example, the length of each of the fifth and sixth channel patterns CH5 and CH6 may be larger than the first to fourth lengths CHL1, CHL2, CHL3, and CHL4 of the first to fourth channel patterns CH1, CH2, CH3, and CH4 described with reference to FIGS. 4A and 4B.

The gate electrodes GE may be provided on the fifth and sixth channel patterns CH5 and CH6. Each of the gate electrodes GE may be vertically overlapped with each of the fifth and sixth channel patterns CH5 and CH6. Each of the gate electrodes GE may include the first to third inner gate electrodes PO1, PO2, and PO3 and the outer gate electrodes PO4. For example, each of the gate electrodes GE may include three outer gate electrodes PO4, which are provided on the third semiconductor pattern SP3 of each of the fifth and sixth channel patterns CH5 and CH6 and are spaced apart from each other.

In some implementations, a plurality of preliminary insulating patterns 105 may be provided on each of the fifth and sixth channel patterns CH5 and CH6. Each of the preliminary insulating patterns 105 may be extended in the second direction D2. More specifically, three preliminary insulating patterns 105 may be placed on the third semiconductor pattern SP3 of each of the fifth and sixth channel patterns CH5 and CH6. That is, the preliminary insulating patterns 105 may be vertically overlapped with the fifth and sixth channel patterns CH5 and CH6. In addition, each of the preliminary insulating patterns 105 may be placed between the outer gate electrodes PO4 of the gate electrodes GE. Accordingly, the preliminary insulating patterns 105 may be spaced apart from each other in the first direction D1.

The gate spacers GS may be placed at both sides of the outer gate electrodes PO4 of the gate electrodes GE. In addition, the gate spacers GS may be extended into regions between the preliminary insulating patterns 105 and the third semiconductor pattern SP3 of each of the fifth and sixth channel patterns CH5 and CH6. The gate spacers GS may be provided to have substantially the same features as those in the implementations of FIGS. 2 and 3A to 3E.

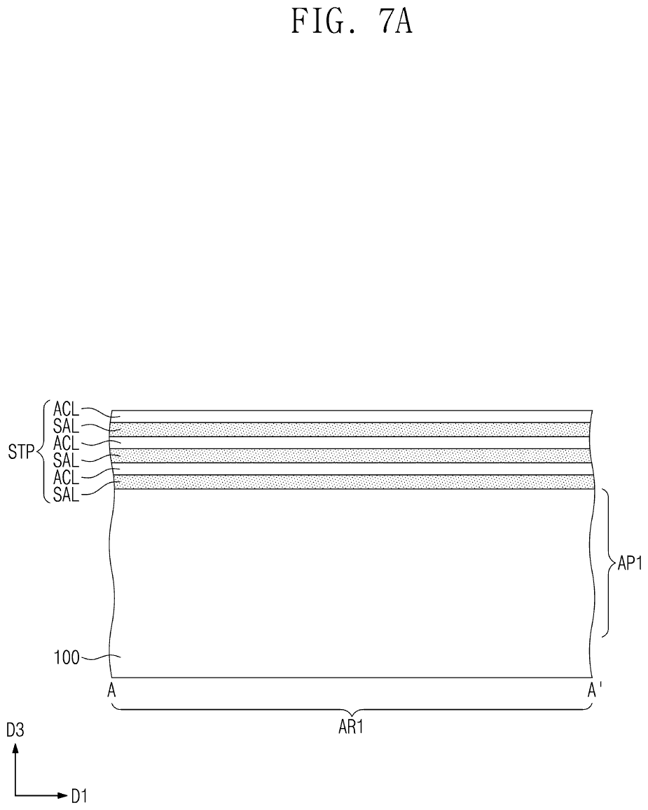

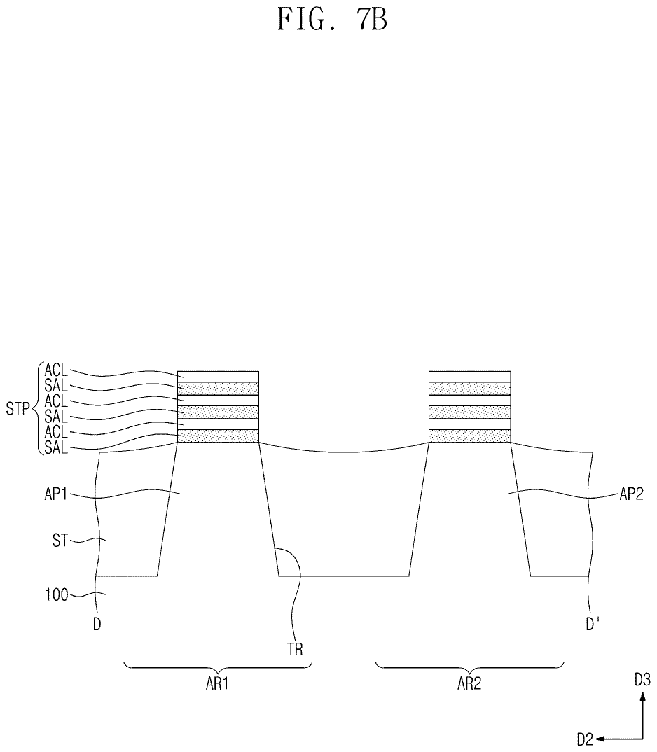

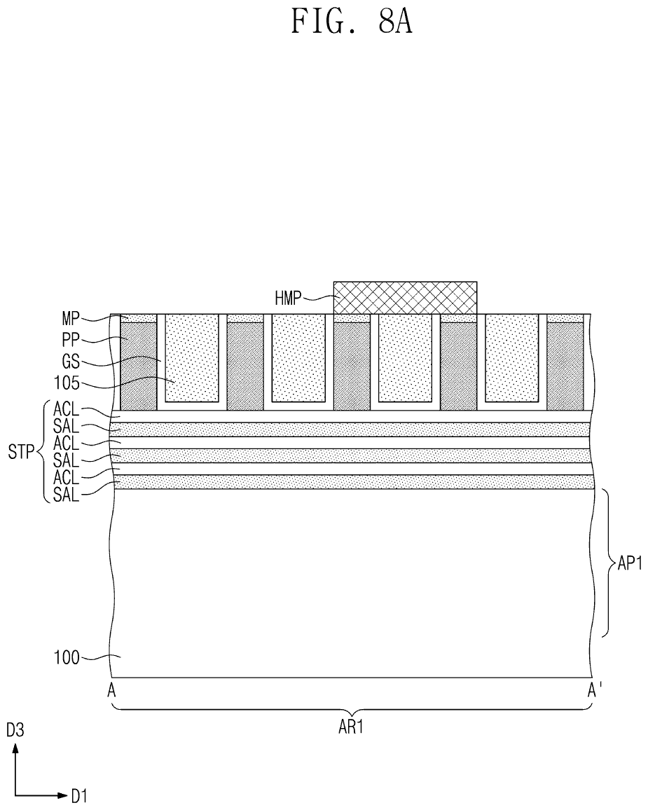

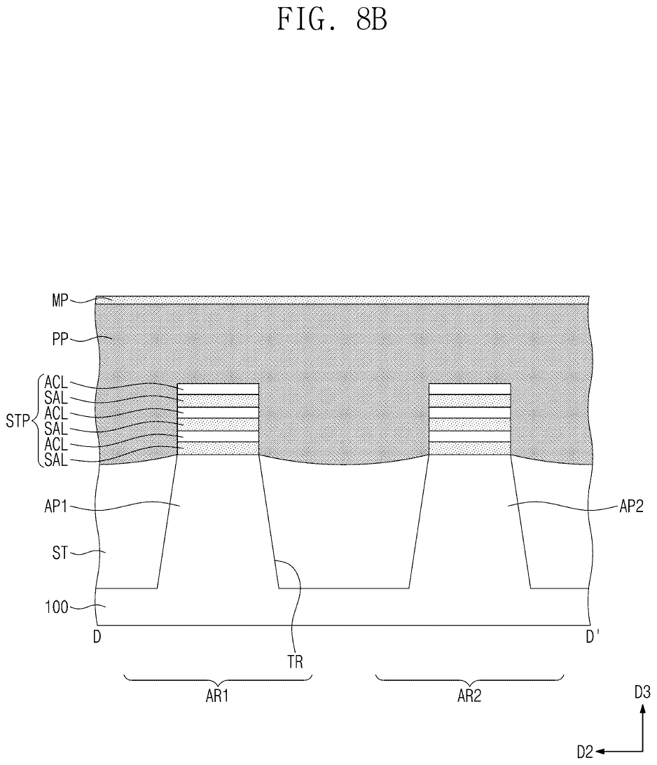

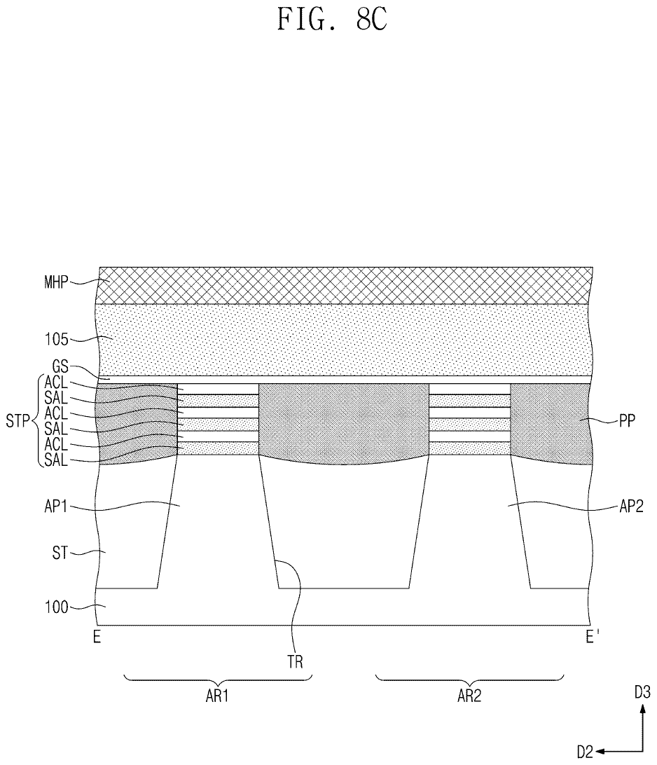

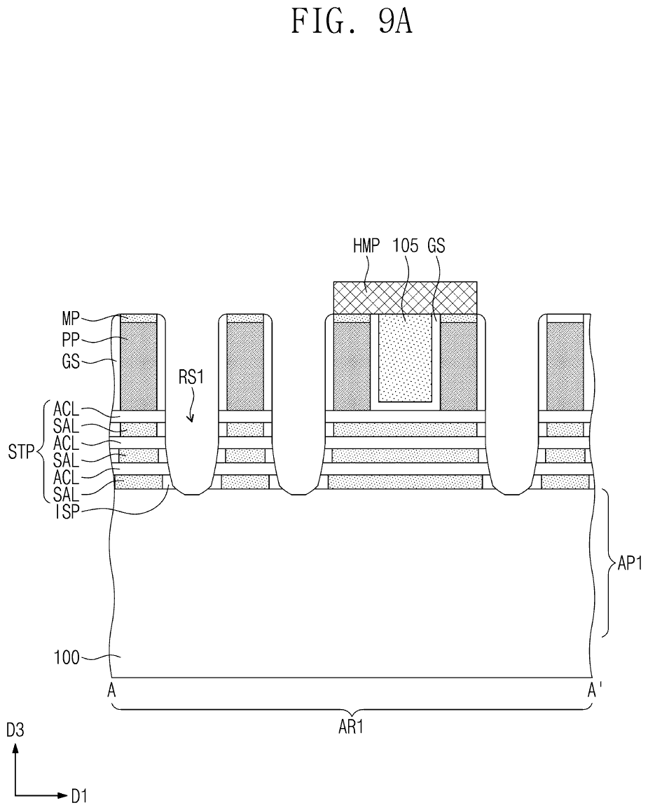

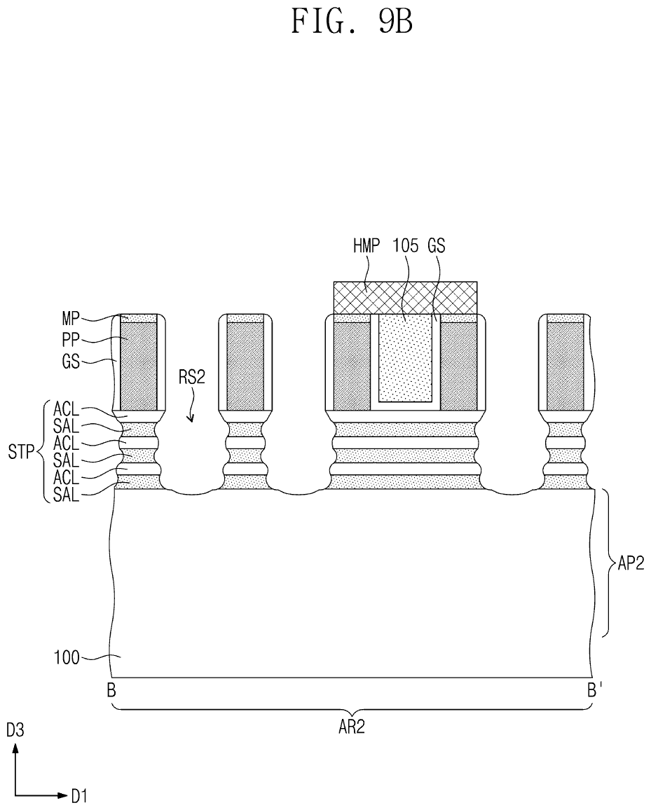

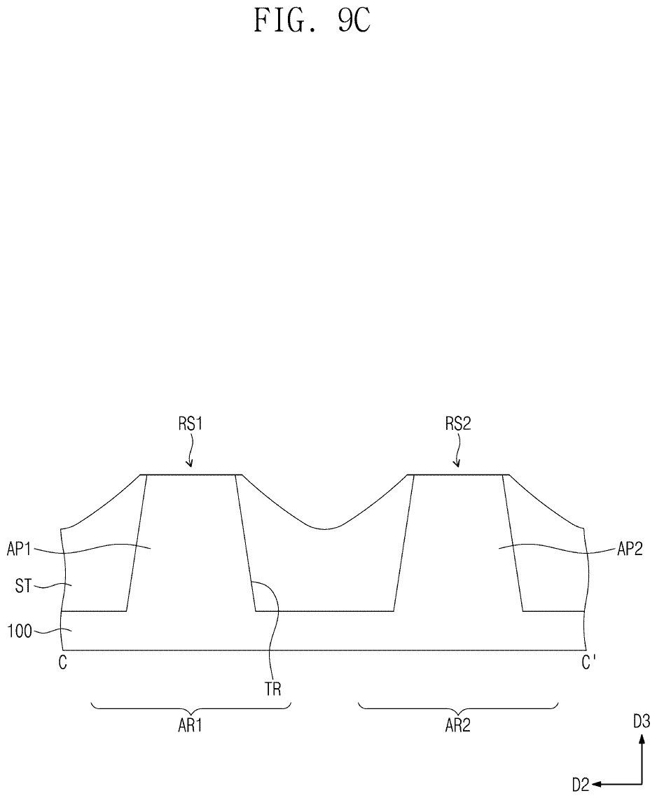

FIGS. 7A, 7B, 8A-8C, 9A-9C, 10A-10E, 11A-11E, and 12A-12E are sectional views illustrating an example of a method of fabricating a semiconductor device according to some implementations. FIGS. 7A, 8A, 9A, 10A, 11A, and 12A are sectional views taken alone the line A-A′ of FIG. 2, FIGS. 9B, 10B, 11B, and 12B are sectional views taken alone the line B-B′ of FIG. 2, FIGS. 9C, 10C, 11C, and 12C are sectional views taken alone the line C-C′ of FIG. 2, FIGS. 7B, 8B, 10D, 11D, and 12D are sectional views taken alone the line D-D′ of FIG. 2, and FIGS. 8C, 10E, 11E, and 12E are sectional views taken alone the line E-E′ of FIG. 2.

In FIGS. 7A and 7B, the substrate 100 including the first and second active regions AR1 and AR2 may be provided. Active layers ACL and sacrificial layers SAL, which are alternately stacked, may be formed on the substrate 100. The active and sacrificial layers ACL and SAL may be formed of or include at least one of silicon (Si), germanium (Ge), or silicon-germanium (SiGe), and here, the active and sacrificial layers ACL and SAL may be formed of different materials from each other.

The sacrificial layers SAL may include a material having an etch selectivity with respect to the active layers ACL. For example, the active layers ACL may be formed of or include silicon, and the sacrificial layers SAL may be formed of or include silicon-germanium. The concentration of the germanium in each of the sacrificial layers SAL may range from about 10 at % to about 30 a%.

Next, a patterning process may be performed using mask patterns, which are formed on the first and second active regions AR1 and AR2 of the substrate 100. Each of the mask patterns may have a line-or bar-shaped structure extending in the first direction D1. The patterning process may be performed to etch a portion of an upper portion of the substrate 100, and as a result, the trench TR may be formed to define the first and second active patterns AP1 and AP2. The first active pattern AP1 may be formed on the first active region AR1. The second active pattern AP2 may be formed on the second active region AR2.

Stacking patterns STP may be formed on the first and second active patterns AP1 and AP2 respectively. Each of the stacking patterns STP may include the active layers ACL and the sacrificial layers SAL, which are alternately stacked on top of each other. During the patterning process of forming the trench TR, the stacking patterns STP may be formed together with the first and second active patterns AP1 and AP2, but the inventive concept is not limited to this example.

After the formation of the stacking patterns STP, the device isolation layer ST may be formed to fill the trench TR. The formation of the device isolation layer ST may include forming an insulating layer on the substrate 100 to cover the first and second active patterns AP1 and AP2 and the stacking patterns STP and recessing the insulating layer to expose the stacking patterns STP. Accordingly, the stacking patterns STP may be placed above the device isolation layer ST and may be exposed to the outside of the device isolation layer ST. That is, the stacking patterns STP may protrude vertically above the device isolation layer ST. The device isolation layer ST may be formed of or include, for example, an insulating material (e.g., silicon oxide).

In FIGS. 8A, 8B, and 8C, sacrificial patterns PP may be formed on the substrate 100 to cross the stacking patterns STP. Each of the sacrificial patterns PP may be formed to have a line-or bar-shaped structure extending in the second direction D2. The sacrificial patterns PP may be spaced apart from each other in the second direction D2 by a specific distance. For example, the sacrificial patterns PP may be spaced apart from each other by the distance of the first pitch PT1 described with reference to FIGS. 4A and 4B.

The formation of the sacrificial patterns PP may include forming a sacrificial layer on the substrate 100 to cover the stacking patterns STP and the device isolation layer ST, forming mask patterns MP on the sacrificial layer, and etching the sacrificial layer through an etching process using the mask patterns MP as an etch mask. The sacrificial patterns PP, which are formed by the etching process, may cover the device isolation layer ST and the side surfaces of the stacking patterns STP. In addition, the sacrificial patterns PP may be formed to cover portions of the top surface of each stacking pattern STP and to expose the remaining portions of the top surface of each stacking pattern STP. The sacrificial patterns PP may be formed of or include, for example, polysilicon.

Next, a pair of the gate spacers GS may be formed on opposite side surfaces of each of the sacrificial patterns PP, and the preliminary insulating patterns 105 may be formed on the gate spacers GS. The formation of the gate spacers GS and the preliminary insulating patterns 105 may include forming a gate spacer layer with a uniform thickness on the substrate 100, forming an insulating layer on the gate spacer layer to fill a space between the sacrificial patterns PP, and performing a planarization process on the insulating layer. The mask patterns MP may be exposed again by the planarization process. Accordingly, the gate spacers GS may be formed from the gate spacer layer, and the preliminary insulating patterns 105 may be formed from the insulating layer. Each of the gate spacers GS may be formed to extend from side surfaces of the sacrificial pattern PP to a region between the preliminary insulating pattern 105 and the stacking pattern STP.

After the formation of the gate spacers GS and the preliminary insulating patterns 105, a hard mask pattern HMP may be formed. The hard mask pattern HMP may be formed on at least one region and may be extended in the second direction D2. For example, the hard mask pattern HMP may be formed on one of the preliminary insulating patterns 105 and on the sacrificial patterns PP at both sides thereof.

In FIGS. 9A, 9B, and 9C, the first recesses RS1 may be formed in the stacking patterns STP on the first active pattern AP1. The second recesses RS2 may be formed in the stacking patterns STP on the second active pattern AP2. Accordingly, the device isolation layer ST may be further recessed.

More specifically, the first recesses RS1 may be formed by an etching process using the mask patterns MP and the hard mask pattern HMP as an etch mask. Each of the first recesses RS1 may be formed between a pair of the sacrificial patterns PP. A width, in the first direction D1, of each of the first recesses RS1 may decrease as a distance to the substrate 100 decreases.

In some implementations, some of the preliminary insulating patterns 105 and portions of the gate spacers GS may be removed together by the etching process. For example, the preliminary insulating patterns 105, which are exposed by the hard mask pattern HMP, may be removed by the etching process. In addition, the gate spacers GS, which are placed next to the removed ones of the preliminary insulating patterns 105, may be partially removed during the etching process. Accordingly, each of the etched gate spacers GS may be locally left on the side surfaces of the sacrificial patterns PP and may have a rounded top portion. Additionally, the preliminary insulating pattern 105, which is not exposed by the hard mask pattern HMP, and the gate spacer GS adjacent thereto may not be removed by the etching process.

The sacrificial layers SAL may be exposed by the first recesses RS1. A selective etching process may be performed on the exposed sacrificial layers SAL. The selective etching process may include a wet etching process of selectively removing silicon-germanium. Each of the sacrificial layers SAL may be laterally indented by the selective etching process. The inner spacers ISP may be formed to fill the indented regions of the sacrificial layers SAL.

The second recesses RS2 may be formed in the stacking patterns STP on the second active pattern AP2 by substantially the same method as that for the first recesses RS1. However, the inner spacers ISP may not be formed in the indented side regions of the sacrificial layers SAL on the second active pattern AP2.

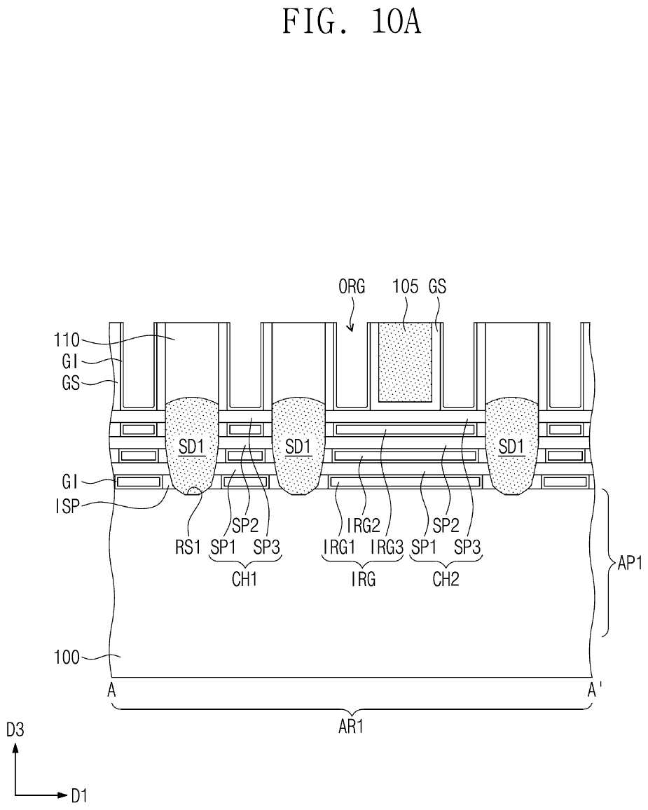

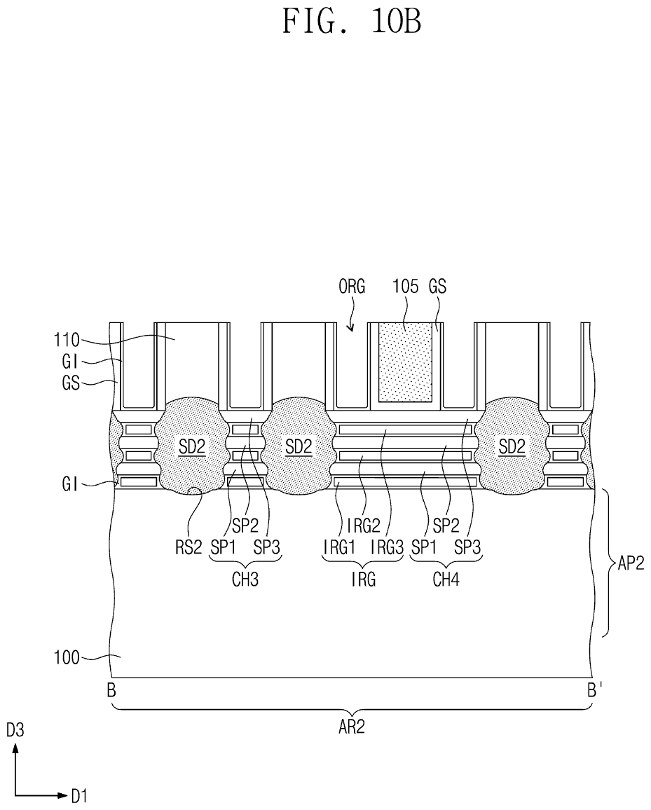

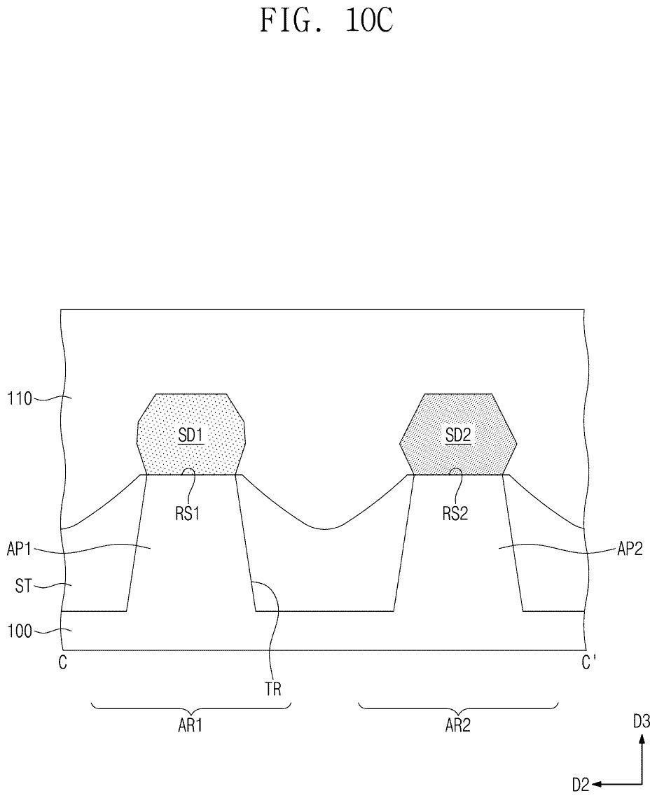

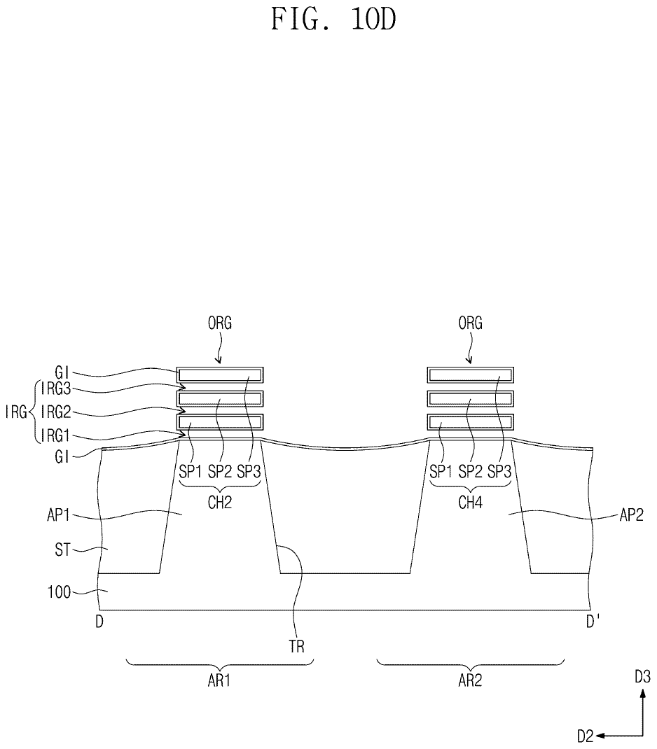

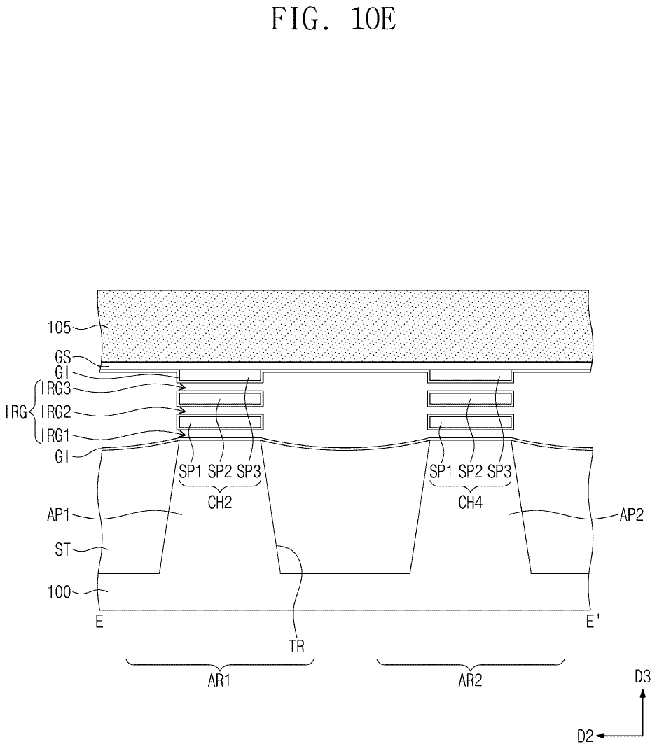

In FIGS. 10A, 10B, 10C, 10D, and 10E, the first source/drain patterns SD1 may be formed in the first recesses RS1, respectively. The first source/drain patterns SD1 may be formed by a selective epitaxial growth (SEG) process using the inner side surfaces of the first recesses RS1 as a seed layer. The first source/drain patterns SD1 may be grown using the first to third semiconductor patterns SP1, SP2, and SP3 (or the active layers ACL) and the substrate 100, which are exposed by the first recesses RS1, as a seed layer. For example, the SEG process may include a chemical vapor deposition (CVD) process and/or a molecular beam epitaxy (MBE) process.

The first source/drain patterns SD1 may include the same semiconductor material (e.g., Si) as the substrate 100. In some implementations, during the formation of the first source/drain patterns SD1, the first source/drain patterns SD1 may be doped in-situ with n-type impurities (e.g., phosphorus, arsenic, or antimony). As another example, impurities may be injected into the first source/drain patterns SD1, after the formation of the first source/drain patterns SD1.

The second source/drain patterns SD2 may be formed in the second recesses RS2, respectively. Similar to the first source/drain patterns SD1, the second source/drain patterns SD2 may be formed by a SEG process using the inner side surfaces of the second recesses RS2 as a seed layer. Unlike the first source/drain patterns SD1, the second source/drain patterns SD2 may be formed of or include a semiconductor material (e.g., SiGe) whose lattice constant is greater than that of a semiconductor material of the substrate 100. The second source/drain patterns SD2 may be doped with impurities (e.g., boron, gallium, or indium) to have a p-type.

Next, the first interlayer insulating layer 110 may be formed to cover the first and second source/drain patterns SD1 and SD2 and the gate spacers GS. The first interlayer insulating layer 110 may be formed of or include, for example, silicon oxide.

After the formation of the first interlayer insulating layer 110, a planarization process may be performed on the first interlayer insulating layer 110 to expose top surfaces of the sacrificial patterns PP. As a result of the planarization process, the mask patterns MP and the hard mask pattern HMP may be fully removed. Accordingly, the first interlayer insulating layer 110 may be formed to have a top surface that is coplanar with the top surfaces of the sacrificial patterns PP, the top surfaces of the gate spacers GS, and the top surface of the preliminary insulating pattern 105. Accordingly, the sacrificial patterns PP and the preliminary insulating pattern 105 may be exposed to the outside.

In some implementations, the exposed sacrificial patterns PP may be selectively removed. Since the sacrificial patterns PP are removed, an outer region ORG may be formed to expose the sacrificial layers SAL. The sacrificial layers SAL, which are exposed through the outer region ORG, may be selectively removed. The preliminary insulating pattern 105 and the active layers ACL may not be removed by the selective removal of the sacrificial layers SAL and may be left after the selective removal process. The left portions of the active layers ACL may form the first to third semiconductor patterns SP1, SP2, and SP3 of the first to fourth channel patterns CH1, CH2, CH3, and CH4. The first and second channel patterns CH1 and CH2 may be formed on the first active pattern AP1. The third and fourth channel patterns CH3 and CH4 may be formed on the second active pattern AP2. Due to the preliminary insulating pattern 105, the first and second channel patterns CH1 and CH2 may have different lengths from each other in the first direction D1, and the third and fourth channel patterns CH3 and CH4 may have different lengths from each other in the first direction D1, as described with reference to FIGS. 4A and 4B.

An inner region IRG may be formed in a space, from which the sacrificial layers SAL is removed. The inner region IRG may include first to third inner regions IRG1, IRG2, and IRG3. For example, the first inner region IRG1 may be formed between the first and second active patterns AP1 and AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

The first to third semiconductor patterns SP1, SP2, and SP3 may be exposed by the first to third inner regions IRG1, IRG2, and IRG3 and the outer region ORG. The gate insulating layer GI may be formed on the exposed surfaces of the first to third semiconductor patterns SP1, SP2, and SP3. The gate insulating layer GI may be formed to enclose each of the first to third semiconductor patterns SP1, SP2, and SP3. Accordingly, the gate insulating layer GI may be formed in the first to third inner regions IRG1, IRG2, and IRG3 and the outer region ORG. A portion of the gate insulating layer GI may cover a bottom surface of the gate spacer GS.

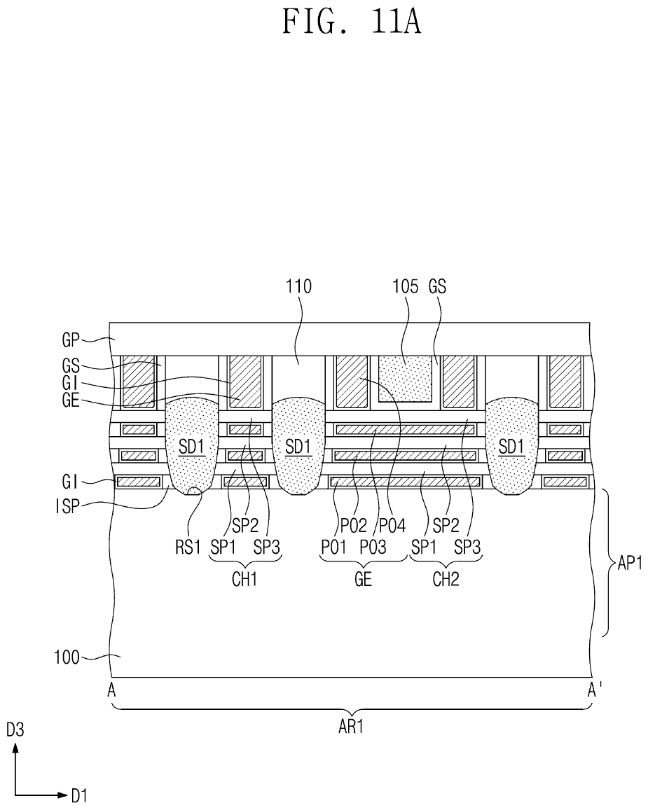

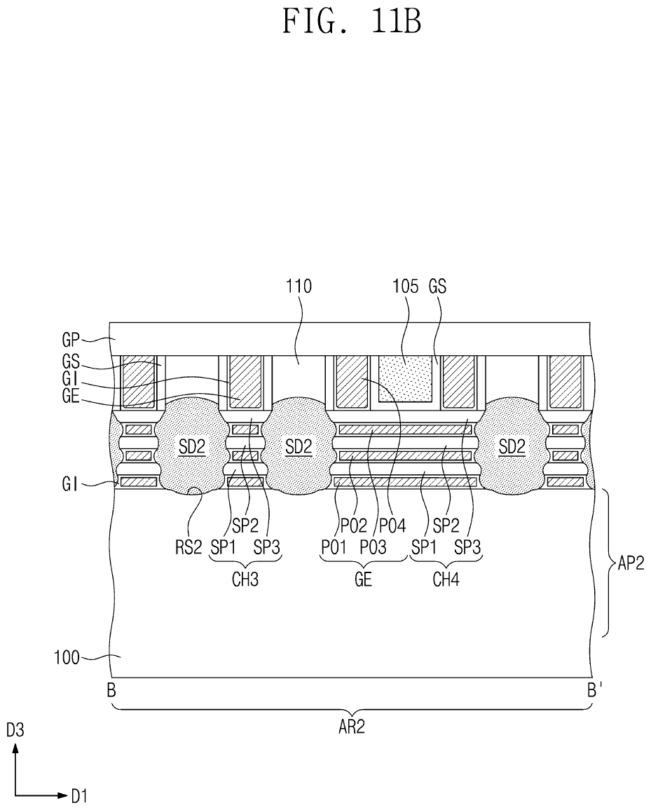

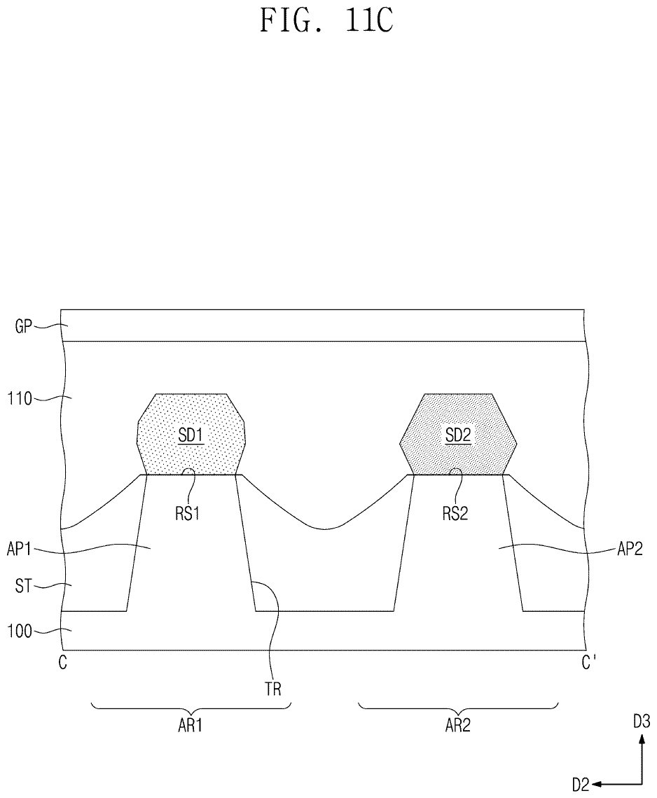

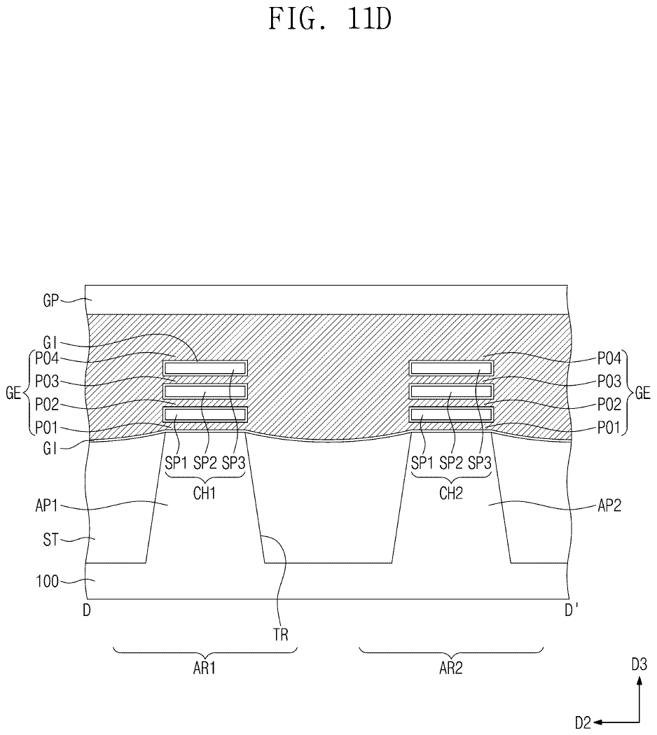

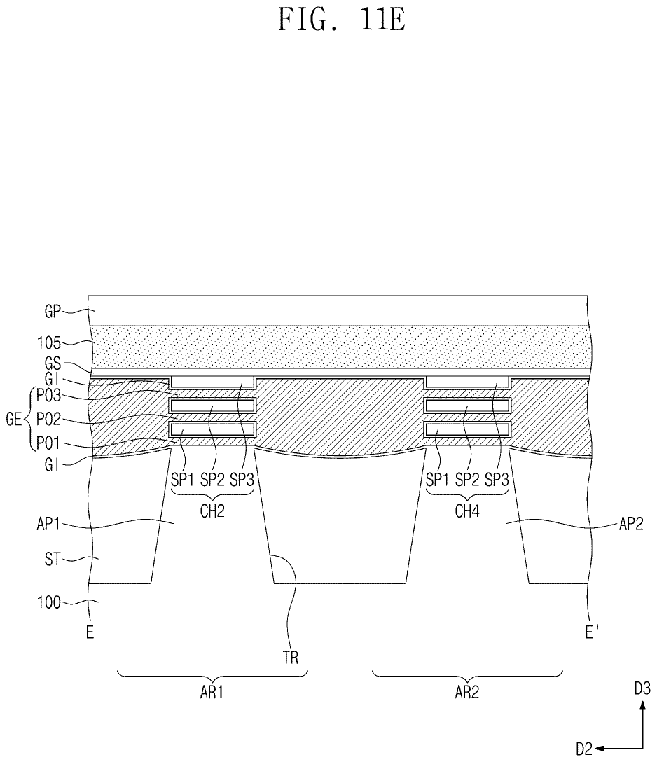

In FIGS. 11A, 11B, 11C, 11D, and 11E, the gate electrodes GE may be formed on the gate insulating layer GI to fill the inner region IRG and the outer region ORG. Each of the gate electrodes GE may include the first to third inner gate electrodes PO1, PO2, and PO3, and the outer gate electrode PO4. The gate electrodes GE on the second and fourth channel patterns CH2 and CH4 may include two outer gate electrodes PO4. For example, the first inner gate electrode PO1 may be formed in the first inner region IRG1, the second inner gate electrode PO2 may be formed in the second inner region IRG2, and the third inner gate electrode PO3 may be formed in the third inner region IRG3. The outer gate electrode PO4 may be formed in the outer region ORG.

Next, a planarization process may be performed. The planarization process may be performed to partially polish the gate spacers GS, the preliminary insulating pattern 105, the first interlayer insulating layer 110, and the gate electrodes GE. Accordingly, the preliminary insulating pattern 105, the first interlayer insulating layer 110, and the gate electrodes GE may have top surfaces located on the same plane or at the same height.

After the planarization process, the gate capping layer GP may be formed. The gate capping layer GP may cover the preliminary insulating pattern 105, the first interlayer insulating layer 110, and the gate electrodes GE. The gate capping layer GP may be formed of or include an insulating material different from the first interlayer insulating layer 110, but the inventive concept is not limited to this example.

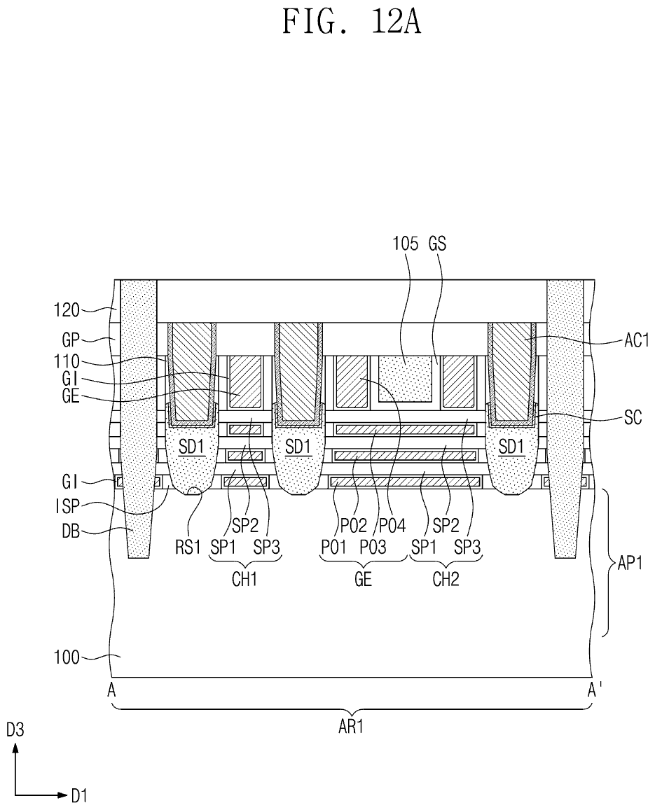

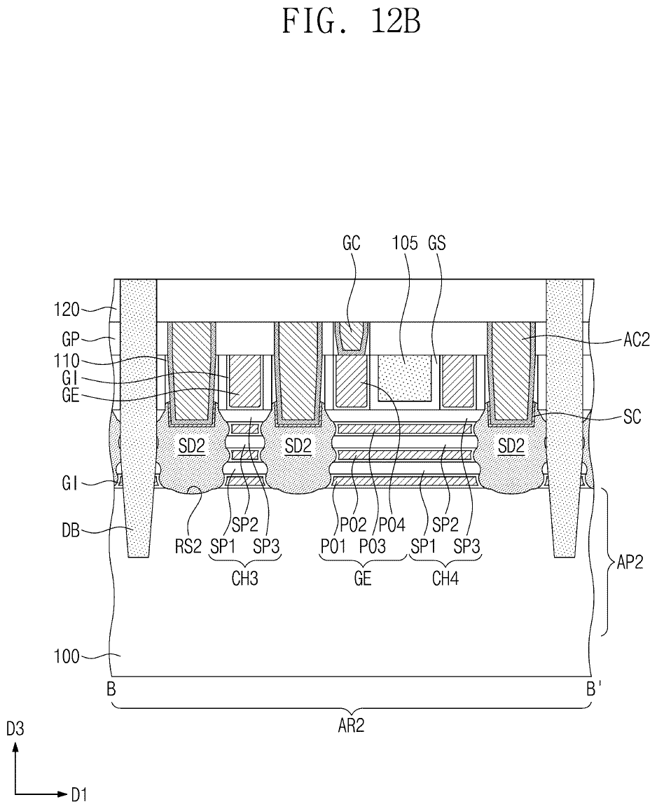

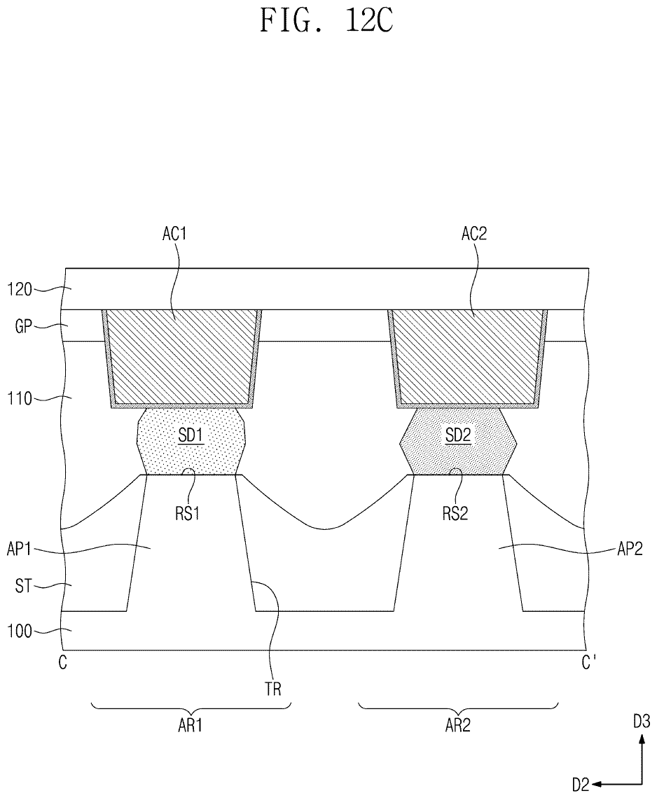

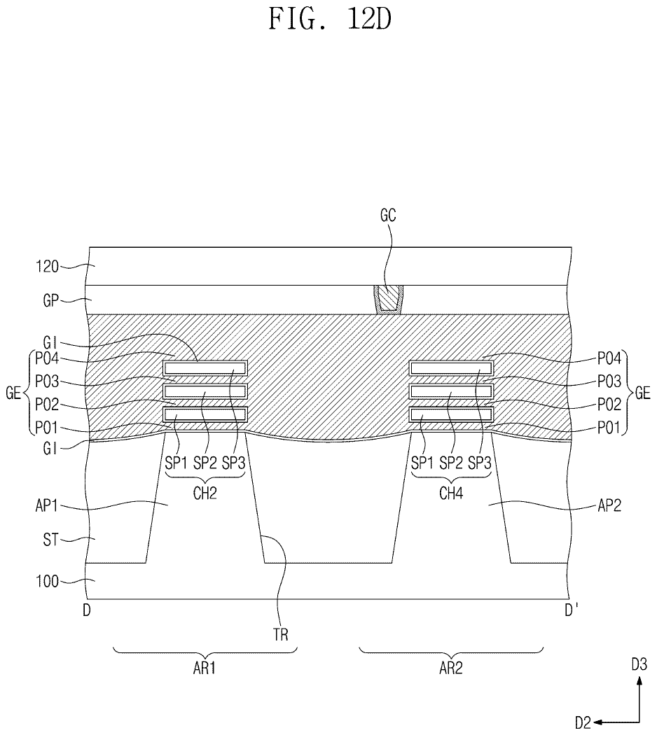

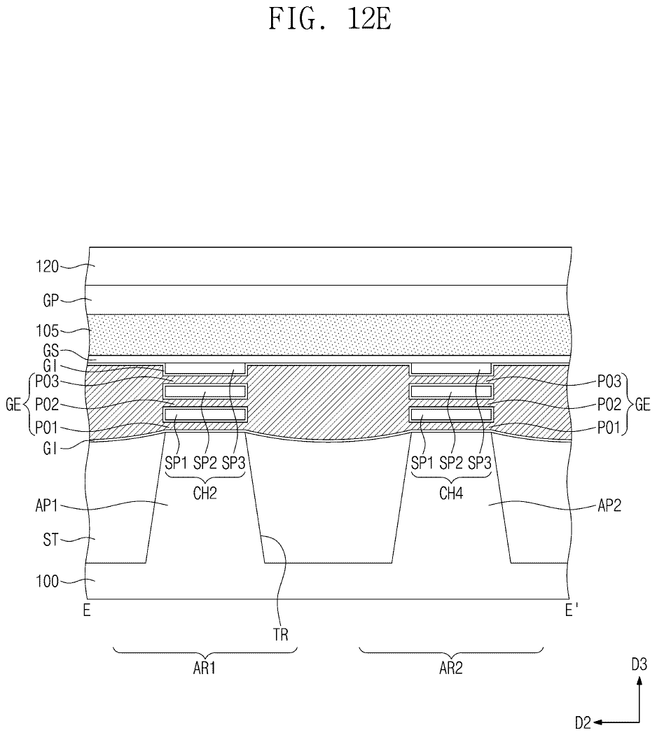

In FIGS. 12A, 12B, 12C, 12D, and 12E, the first active contacts AC1 and the second active contacts AC2 may be formed to penetrate the first interlayer insulating layer 110 and the gate capping layer GP. The first active contacts AC1 may be connected to upper portions of corresponding ones of the first source/drain patterns SD1. The second active contacts AC2 may be connected to upper portions of corresponding ones of the second source/drain patterns SD2. For example, the first active contacts AC1 and the second active contacts AC2 may be formed at the same time.

During the process of forming the first and second active contacts AC1 and AC2, the metal-semiconductor compound layer SC may be formed between the first source/drain patterns SD1 and the first active contacts AC1 and between the second source/drain patterns SD2 and the second active contacts AC2.

The gate contacts GC may be formed to penetrate the gate capping layer GP. The gate contacts GC may be in contact with top surfaces of the gate electrodes GE. For example, the gate contacts GC may be formed in substantially the same manner as the process of forming the first and second active contacts AC1 and AC2.

Next, the second interlayer insulating layer 120 may be formed on the gate capping layer GP, and then, the division structures DB may be formed. The division structures DB may be formed to penetrate the first and second interlayer insulating layers 110 and 120 and the gate capping layer and may be extended into upper portions of the first and second active patterns AP1 and AP2. The division structures DB may be formed of or include an insulating material (e.g., silicon oxide or silicon nitride).

In FIGS. 3A, 3B, 3C, 3D, and 3E, the third interlayer insulating layer 130 may be formed on the second interlayer insulating layer 120. The third interlayer insulating layer 130 may cover a top surface of the second interlayer insulating layer 120. The first metal layer M1 including the first vias VI1, the first power line M1_R1, the second power line M1_R2, and the first interconnection lines M1_I may be formed in the third interlayer insulating layer 130.

Next, the fourth interlayer insulating layer 140 may be formed on the third interlayer insulating layer 130. The second metal layer M2 including the second interconnection lines M2_I may be formed in the fourth interlayer insulating layer 140.

In some implementations, transistors, which are adjacent to each other, may be formed to have different channel lengths. In addition, the transistors with different channel lengths may be formed at the same time. Accordingly, it may be possible to simplify the process of fabricating a semiconductor device.

In some implementations, transistors with different channel lengths may be provided in a s ingle logic cell. Accordingly, transistors with various channel lengths may form a single logic cell. In addition, it may be possible to form transistors with different channel lengths at the same time. Accordingly, it may be possible to simplify a process of fabricating a semiconductor device.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
an active pattern on a substrate, the active pattern extending in a first direction;
a first channel pattern and a second channel pattern on the active pattern and spaced apart from each other in the first direction;
source/drain patterns at sides of the first channel pattern and the second channel pattern; and
gate electrodes on the first channel pattern and the second channel pattern,
wherein the first channel pattern and the second channel pattern are adjacent to a same source/drain pattern of the source/drain patterns, and
wherein a first length of the first channel pattern in the first direction is less than a second length of the second channel pattern in the first direction.

2. The semiconductor device of claim 1, wherein the second length of the second channel pattern is greater than two times the first length of the first channel pattern.

3. The semiconductor device of claim 1, comprising a pair of division structures extending into the active pattern,
wherein the first channel pattern and the second channel pattern are between the division structures.

4. The semiconductor device of claim 1,
wherein the gate electrodes comprise a first gate electrode and a second gate electrode, and
wherein the first gate electrode comprises at least one first inner gate electrode among the first channel pattern, and a first outer gate electrode on the first channel pattern, wherein the second gate electrode comprises at least one second inner gate electrode among the second channel pattern and a plurality of second outer gate electrodes on the second channel pattern.

5. The semiconductor device of claim 4,
wherein the at least one first inner gate electrodes among the first channel pattern have different lengths from the at least one second inner gate electrodes among the second channel pattern in the first direction, and
wherein the first outer gate electrode on the first channel pattern and the plurality of second outer gate electrodes on the second channel pattern have the same length in the first direction.

6. The semiconductor device of claim 4, further comprising a preliminary insulating pattern between the plurality of second outer gate electrodes on the second channel pattern.

7. The semiconductor device of claim 6, wherein a top surface of the preliminary insulating pattern is on a same plane as a top surface of the plurality of second outer gate electrodes.

8. The semiconductor device of claim 6,
wherein the preliminary insulating pattern comprises a plurality of preliminary insulating patterns, and
wherein the plurality of preliminary insulating patterns are spaced apart from each other.

9. The semiconductor device of claim 6, further comprising a gate spacer between the preliminary insulating pattern and the plurality of second outer gate electrodes,
wherein the gate spacer extends into a region between the preliminary insulating pattern and the second channel pattern.

10. The semiconductor device of claim 9, wherein the gate spacer is in contact with a portion of the second channel pattern.

11. A semiconductor device, comprising:
an active pattern on a substrate, the active pattern extending in a first direction;
a channel pattern including a first semiconductor pattern, a second semiconductor pattern, and a third semiconductor pattern that are spaced apart from each other on the active pattern;
source/drain patterns at sides of the channel pattern;
inner gate electrodes among the first semiconductor pattern, the second semiconductor pattern, and the third semiconductor pattern;
outer gate electrodes on the third semiconductor pattern;
a preliminary insulating pattern between the outer gate electrodes; and
a gate spacer between the outer gate electrodes and the preliminary insulating pattern,
wherein the preliminary insulating pattern vertically overlaps with the first semiconductor pattern, the second semiconductor pattern, and the third semiconductor pattern.

12. The semiconductor device of claim 11,
wherein the preliminary insulating pattern is on the third semiconductor pattern, and
wherein the gate spacer extends between the preliminary insulating pattern and the third semiconductor pattern.

13. The semiconductor device of claim 11, wherein a top surface of the third semiconductor pattern contacts the gate spacer.

14. The semiconductor device of claim 11, comprising a gate insulating layer between the first semiconductor pattern, the second semiconductor pattern, and the third semiconductor pattern and the inner gate electrodes,
wherein the gate insulating layer is between the third semiconductor pattern and the outer gate electrodes, and
wherein the gate insulating layer extends onto a bottom surface of the gate spacer.

15. The semiconductor device of claim 11, wherein a length of the inner gate electrodes in the first direction is greater than a length of the outer gate electrodes in the first direction.

16. The semiconductor device of claim 15, wherein the length of the inner gate electrodes is greater than two times the length of the outer gate electrodes.

17. The semiconductor device of claim 11, wherein top surfaces of the outer gate electrodes are at a same plane as a top surface of the preliminary insulating pattern.

18. A semiconductor device, comprising:
a first active pattern and a second active pattern provided on a substrate, the first active pattern being spaced apart from the second active pattern;
a first channel pattern and a second channel pattern on the first active pattern;
a third channel pattern and a fourth channel pattern on the second active pattern;
first source/drain patterns provided at sides of the first and second channel patterns;
second source/drain patterns provided at sides of the third and fourth channel patterns;
gate electrodes on the first channel pattern, the second channel pattern, the third channel pattern, and the fourth channel pattern;
a gate insulating layer between the gate electrodes and each of the first channel pattern, the second channel pattern, the third channel pattern, and the fourth channel pattern; and
a preliminary insulating pattern on the second channel pattern and the fourth channel pattern,
wherein the first source/drain patterns are arranged at different distances from one another, and
wherein the second source/drain patterns are arranged at different distances from one another.

19. The semiconductor device of claim 18,
wherein the first channel pattern and the second channel pattern are adjacent to a same source/drain pattern of the first source/drain patterns, and
wherein the third channel pattern and the fourth channel pattern are adjacent to a same source/drain pattern of the second source/drain patterns.

20. The semiconductor device of claim 18, wherein a length of the first channel pattern and the third channel pattern in a first direction is less than a length of the second channel pattern and the fourth channel pattern in the first direction.
